(19) United States
(12) Patent Application Publication
(10) Pub. No.: US 2026/0002045 A1
(43) Pub. Date: Jan. 1, 2026

(54) BASE MATERIAL AND METHOD FOR PRODUCING STRUCTURE INCLUDING PHASE-SEPARATED STRUCTURE

(71) Applicant: TOKYO OHKA KOGYO CO., LTD., Kawasaki-shi (JP)

(72) Inventors: Junichi Tsuchiya, Kawasaki-shi (JP); Ryutaro Sugawara, Kawasaki-shi (JP)

(21) Appl. No.: 19/241,027

(22) Filed: Jun. 17, 2025

(30) Foreign Application Priority Data
Jun. 27, 2024 (JP) 2024-104098

(51) Int. Cl. C09D 153/00; C08F 297/02

(52) U.S. Cl. CPC C09D 153/00; C08F 297/023; C08F 297/026

(57) ABSTRACT

A base material capable of forming a phase-separated structure excellent in horizontal orientation. The base material contains a block copolymer including a block (A1) having a constituent unit represented by the following Formula (a1) and a block (A2) having a constituent unit represented by the following Formula (a2), and a molar ratio of the constituent unit of the block (A2) of more than 0 mol % and 40 mol % or less. In Formula (a1), R^{a11} represents a hydrogen atom, R^{a12} represents a substituent, and n is an integer of 0 to 5; and in Formula (a2), R^{a21} represents a hydrogen atom, L¹ represents a single bond, and Y¹ represents a divalent linking group having 1 to 15 carbon atoms

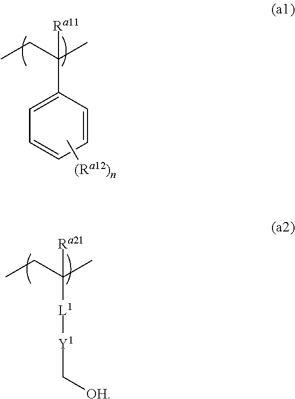

### RELATED APPLICATIONS

This application claims priority to Japanese Patent Application No. 2024-104098, filed Jun. 27, 2024, the entire content of which is incorporated herein by reference.

### BACKGROUND OF THE INVENTION

### Field of the Invention

The present invention relates to a base material and a method for producing a structure including a phase-separated structure.

### Related Art

In recent years, following further miniaturization of a large-scale integrated circuit (LSI), a technique for processing a finer structure has been demanded. In response to such a demand, a technique has been developed for forming a finer structure by utilizing a phase-separated structure formed by self-organization of a block copolymer in which mutually incompatible blocks are bonded to each other.

In order to utilize the phase-separated structure of the block copolymer, it is essential to form a self-organized nanostructure, which is formed by microphase separation, only in a specific region and to orient the same in a desired direction. In order to control a position and an orientation of the nanostructure, processes such as graphoepitaxy for controlling a phase separation pattern by a guide pattern and chemical epitaxy for controlling a phase separation pattern based on a difference in a chemical state of a substrate have been proposed.

As a method for forming a fine pattern by bringing a block copolymer to phase separation, for example, a method for forming a base material layer on a substrate is disclosed. For example, Patent Document 1 discloses a base material containing a copolymer in which a constituent unit derived from styrene and a constituent unit derived from hydroxyethyl acrylate are randomly oriented.
Patent Document 1: Japanese Patent No. 6475963

### SUMMARY OF THE INVENTION

In a case where a polymer mainly having a constituent unit derived from styrene or a derivative thereof is used as the base material, it is ideal that the phase-separated structure formed by the block copolymer is horizontally oriented with respect to a surface of the substrate. However, in the base material in the related art as disclosed in Patent Document 1, when a block copolymer having a large period (L0) of a structure is used for phase separation, there is a problem that a vertically oriented phase-separated structure is mixed.

The present invention has been made in view of the above circumstances, and an object of the present invention is to provide a base material capable of forming a phase-separated structure excellent in horizontal orientation, and a method for producing a structure including the phase-separated structure.

As a result of intensive studies to solve the above problem, the present inventors have found that the above problem can be solved by using a base material containing a predetermined block polymer (A), and have completed the invention. Specifically, the present invention provides the following aspects.

A first aspect of the present invention is a base material for bringing a block copolymer-containing layer to phase separation, the base material containing:
a block copolymer (A) including a block (A1) and a block (A2),
   the block (A1) having a constituent unit represented by the Formula (a1) described below,
   the block (A2) having a constituent unit represented by the Formula (a2) described below,
the block copolymer (A) having no constituent unit derived from an alkyl (meth)acrylate,
the block copolymer (A) having a molar ratio of the constituent unit of the block (A2) of more than 0 mol % and 40 mol % or less with respect to a total of the constituent unit of the block (A1) and the constituent unit of the block (A2).

A second aspect of the present invention is a method for producing a structure including a phase-separated structure, the method including:
applying the base material as described in the first aspect onto a substrate to form a base material layer;
forming a block copolymer-containing layer on the base material layer; and
bringing the block copolymer-containing layer to phase separation.

According to the present invention, it is possible to provide a base material capable of forming a phase-separated structure excellent in horizontal orientation, and a method for producing a structure including the phase-separated structure.

### BRIEF DESCRIPTION OF THE DRAWINGS

FIG. 1 is a schematic process diagram illustrating an embodiment of a method for producing a structure having a phase-separated structure;

FIG. 2 is a diagram illustrating an embodiment of an optional step;

FIG. 3 is a diagram schematically illustrating examples of structures including a phase-separated structure, which are produced by the method for producing a structure including a phase-separated structure according to the embodiment;

FIG. 4 illustrates examples of SEM aerial images of the structures including a phase-separated structure, which are produced by the method for producing a structure including a phase-separated structure according to the embodiment; and FIG. 5 is a diagram illustrating an example corresponding to each evaluation criterion for horizontal orientation in Examples.

### DETAILED DESCRIPTION OF THE INVENTION

Hereinafter, embodiments of the present invention will be described in detail, but the present invention is not limited to the following embodiments, and can be implemented with modifications as appropriate within the scope of the object of the present invention.

### <<Base Material>>

The base material is used for bringing a layer containing a block copolymer to phase separation, and contains a block copolymer (A). The block copolymer (A) includes a block (A1) and a block (A2), and has no constituent unit derived from an alkyl (meth)acrylate. The block (A1) has a constituent unit represented by the following Formula (a1). The block (A2) has a constituent unit represented by the following Formula (a2). A ratio of the number of moles of the constituent unit constituting the block (A2) to a total of the number of moles of the constituent unit constituting the block (A1) and the number of moles of the constituent unit constituting the block (A2) is more than 0 mol % and 40 mol % or less.

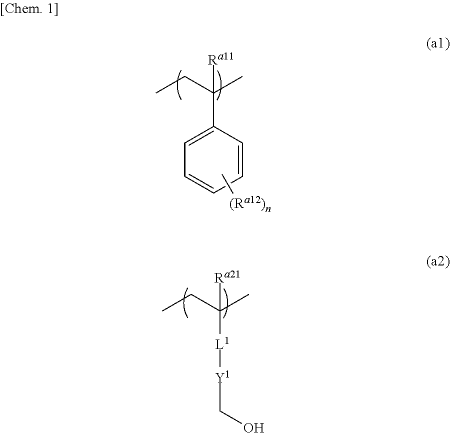

(In Formula (a1), R^{a11} represents a hydrogen atom, an alkyl group having 1 or more and 5 or less carbon atoms, or a halogenated alkyl group having 1 or more and 5 or less carbon atoms, R^{a12} represents a substituent, and n is an integer of 0 or more and 5 or less. In Formula (a2), R^{a21} represents a hydrogen atom, an alkyl group having 1 or more and 5 or less carbon atoms, or a halogenated alkyl group having 1 or more and 5 or less carbon atoms, L¹ represents a single bond or a divalent linking group, and Y¹ represents a divalent linking group having 1 or more and 15 or less carbon atoms).

By using such a base material, a phase-separated structure excellent in horizontal orientation can be formed. The reason why this effect is obtained is not necessarily clear, but is presumed to be as follows.

In many cases, a polymer used for the base material adheres to the substrate via a polar group such as a hydroxy group. Such a polymer in the related art, however, includes a polymer having a polar group at a terminal of a main chain, in which the number of polar groups is small, and adhesion to the substrate is insufficient. Therefore, a density of a polymer brush is low, which makes it difficult to obtain good horizontal orientation. In addition, the polymer in the related art also includes a random copolymer in which a constituent unit having a polar group and another constituent unit are randomly oriented. In such a copolymer, the polar group may appear on a surface layer of a base material layer, or a polar group in a portion other than the terminal of the polymer and the substrate may adhere to each other, which inhibit formation of the polymer brush and adversely affect the horizontal orientation.

On the other hand, in the block copolymer (A) used for the base material of the first aspect, constituent units each having a hydroxy group form a block(s), which brings good adhesion to the substrate. Therefore, the base material of the first aspect has a higher density of the polymer brush by using the block copolymer (A). The horizontal orientation will be improved for this reason.

### <Block Copolymer (A)>

The block copolymer (A) includes a block (A1) and a block (A2), and has no constituent unit derived from an alkyl (meth)acrylate.

The block copolymer (A) may include a block (another block) other than the block (A1) and the block (A2), but preferably includes no other block. In a case where the block copolymer (A) includes another block, it is preferable that the block (A2) is not sandwiched between blocks other than the block (A2) (positioned on one terminal side of a main chain of the block copolymer (A)).

### [Block (A1)]

The block (A1) has a constituent unit represented by the following Formula (a1).

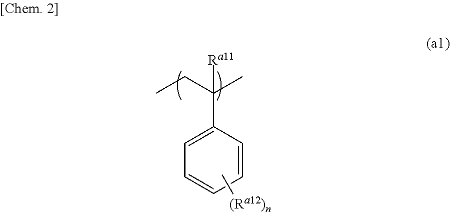

(In Formula (a1), R^{a11} represents a hydrogen atom, an alkyl group having 1 or more and 5 or less carbon atoms, or a halogenated alkyl group having 1 or more and 5 or less carbon atoms, R^{a12} represents a substituent, and n is an integer of 0 or more and 5 or less.)

Examples of the alkyl group having 1 or more and 5 or less carbon atoms as R^{a11} include a methyl group, an ethyl group, an n-propyl group, an isopropyl group, an n-butyl group, a sec-butyl group, an isobutyl group, a tert-butyl group, an n-pentyl group, a neopentyl group, an isopentyl group, a sec-pentyl group, a 3-pentyl group, and a tert-pentyl group. The halogenated alkyl group having 1 or more and 5 or less carbon atoms is a group in which some or all of hydrogen atoms in an alkyl group having 1 or more and 5 or less carbon atoms are substituted with halogen atoms. The halogen atom is particularly preferably a fluorine atom.

Examples of the substituent represented by R^{a12} include a hydrocarbon group which may have a substituent, and a halogen atom. Examples of the hydrocarbon group represented by R^{a12} which may have a substituent include an alkyl group which may have a substituent, a cycloalkyl group which may have a substituent, and an aryl group which may have a substituent. Among these, the alkyl group which may have a substituent is preferable. The number of carbon atoms of the alkyl group represented by R^{a12} which may have a substituent is preferably 1 or more and 10 or less, more preferably 1 or more and 5 or less, and further preferably 1 or more and 3 or less. The substituent which the alkyl group represented by R^{a12} may have is preferably an alkyl group which may be interrupted by an oxygen atom and may be substituted with an alkylsilyl group. Specific examples thereof include an alkyl group, an alkylsilyl group, an alkylsilylalkyl group, an alkylsilyloxy group, an alkylsilyloxyalkyl group, and an alkoxy group.

Examples of the alkyl group represented by R^{a12} include a methyl group, an ethyl group, an n-propyl group, an isopropyl group, an n-butyl group, a sec-butyl group, an isobutyl group, and a tert-butyl group.

The alkylsilyl group represented by R^{a12} is preferably a trialkylsilyl group. Specific examples thereof include a trimethylsilyl group. The alkylsilylalkyl group represented by R^{a12} is preferably a trialkylsilylalkyl group. Specific examples thereof include a trimethylsilylmethyl group, a 2-trimethylsilylethyl group, and a 3-trimethylsilyl-n-propyl group. The alkylsilyloxy group represented by R^{a12} is preferably a trialkylsilyloxy group. Specific examples thereof include a trimethylsilyloxy group. The alkylsilyloxyalkyl group represented by R^{a12} is preferably a trialkylsilyloxyalkyl group. Specific examples thereof include a trimethylsilyloxymethyl group, a 2-trimethylsilyloxyethyl group, and a 3-trimethylsilyloxy-n-propyl group. Examples of the alkoxy group represented by R^{a12} include a methoxy group, an ethoxy group, an n-propoxy group, an isopropoxy group, an n-butoxy group, a sec-butoxy group, an isobutoxy group, and a tert-butoxy group.

Preferably, n is an integer of 0 or more and 3 or less, also preferably 0 or 1.

Specific examples of the constituent unit represented by Formula (a1) are shown below. In the following formulae, R^{a13} represents a hydrogen atom, a methyl group, or a trifluoromethyl group.

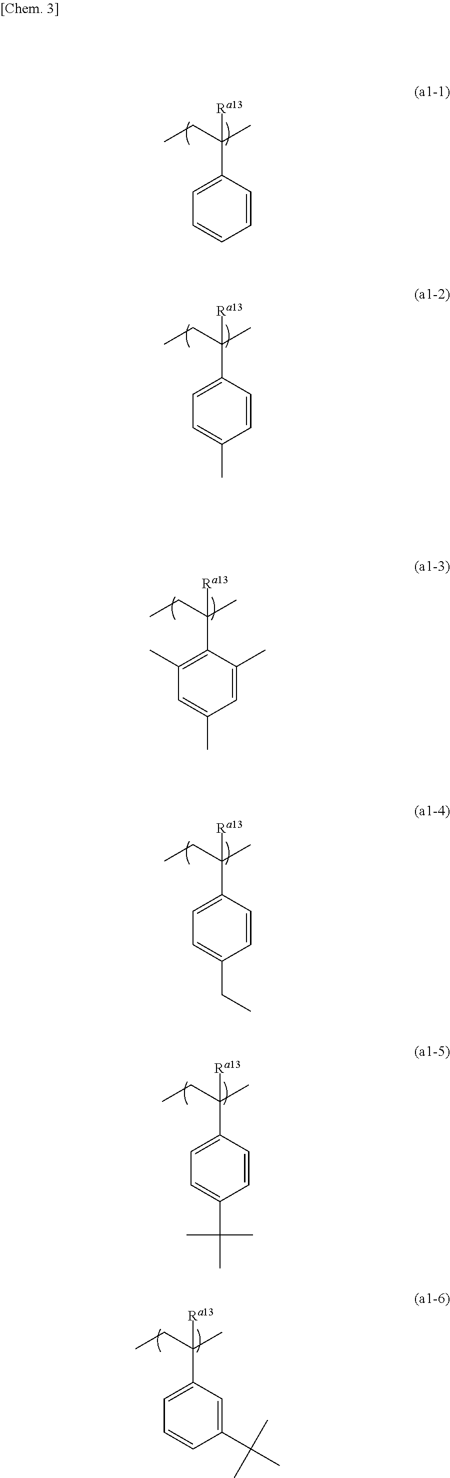

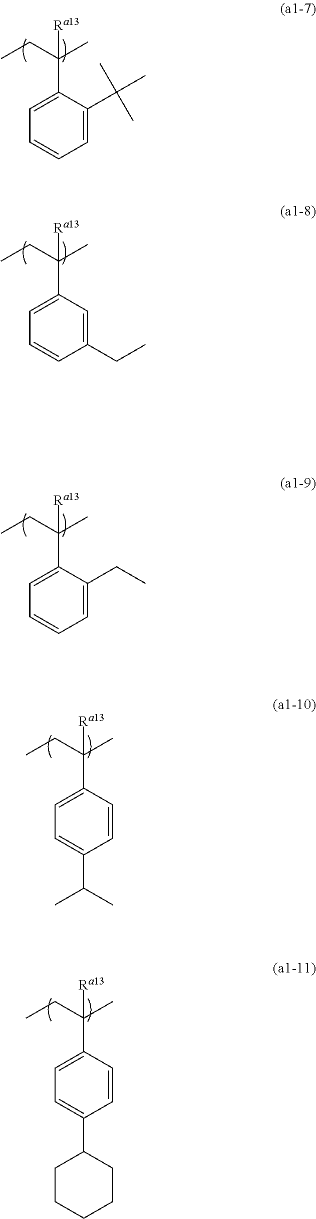

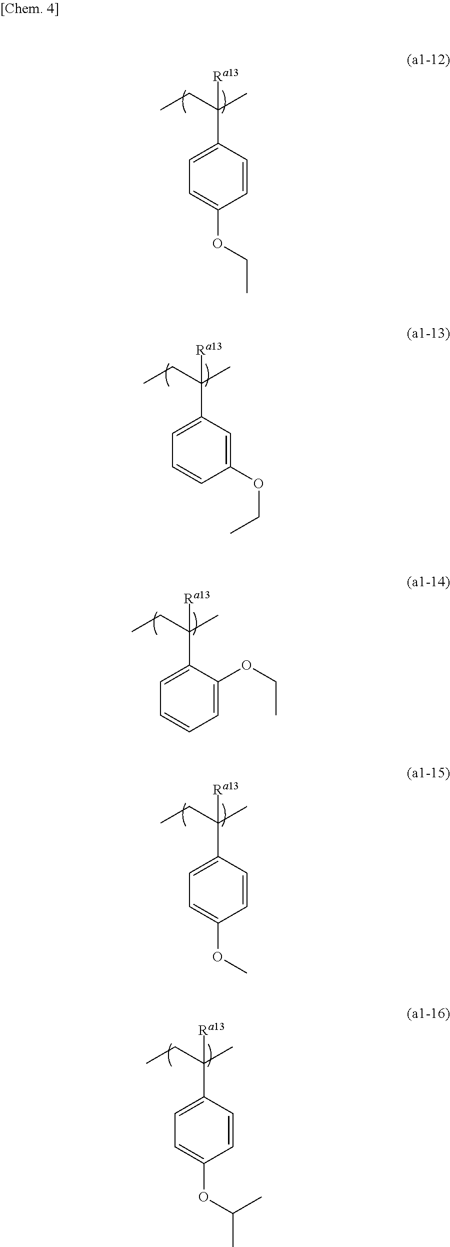

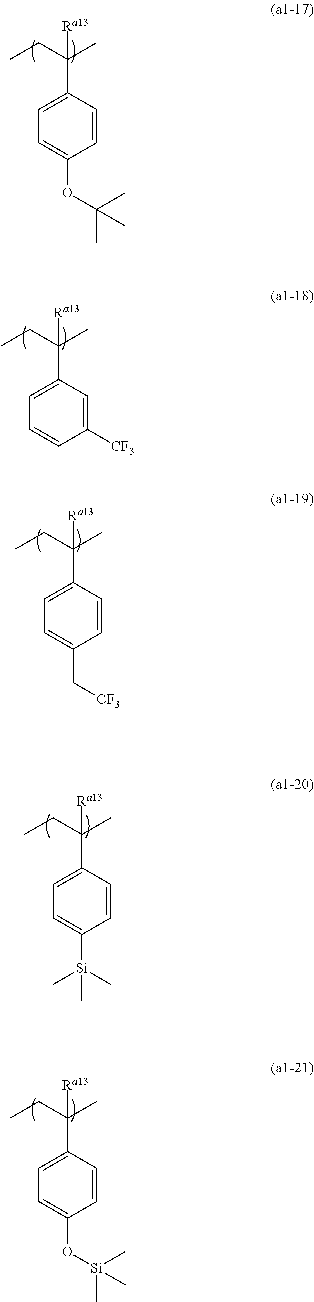

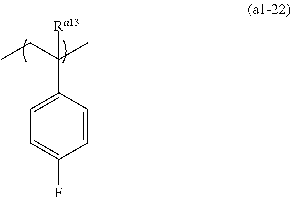

A molar ratio of the constituent unit of the block (A1) to all the constituent units of the block copolymer (A) is preferably 60 mol % or more, more preferably 65 mol % or more, and still more preferably 70 mol % or more. In addition, the above ratio is preferably 99 mol % or less, and more preferably 97 mol % or less. Within the above numerical range, good horizontal orientation is easily obtained.

### [Block (A2)]

The block (A2) has a constituent unit represented by the following Formula (a2).

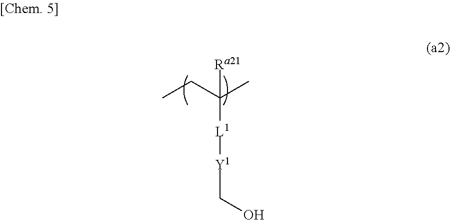

(In Formula (a2), R^{a21} represents a hydrogen atom, an alkyl group having 1 or more and 5 or less carbon atoms, or a halogenated alkyl group having 1 or more and 5 or less carbon atoms, L¹ represents a single bond or a divalent linking group, and Y¹ represents a divalent linking group having 1 or more and 15 or less carbon atoms.)

The alkyl group having 1 or more and 5 or less carbon atoms and the halogenated alkyl group having 1 or more and 5 or less carbon atoms represented by R^{a21} are the same as those groups represented by R^{a11}.

The divalent linking group represented by L¹ is preferably a divalent linking group containing a heteroatom. Examples of the heteroatom include an oxygen atom, a nitrogen atom, a sulfur atom, and a halogen atom.

Examples of the divalent linking group containing a heteroatom include groups represented by —O—, —C(═O)—O—, —C(═O)—, —O—C(═O)—O—, —C(═O)—NR—, —NR—, —NR—C(═NR)—, —S—, —S(═O)₂—, —S(═O)₂—O—, -L¹¹-O—, -L¹¹-O-L¹¹-, -L¹¹-C(═O)—O—, —C(═O)—O-L¹¹-, -L¹¹-C(═O)—O-L¹¹-, and -L¹¹-S(═O)₂—O-L¹¹-[in the formulae, each R independently represents a hydrogen atom or a substituent (for example, an alkyl group, an acyl group, or the like). Each L¹¹ independently represents a chain aliphatic hydrocarbon group.]. In the present description, an orientation of a bond of a divalent group is not particularly limited unless otherwise specified.

The number of carbon atoms of the alkyl group and the acyl group represented by R is preferably 1 or more and 10 or less, and more preferably 1 or more and 5 or less.

The chain aliphatic hydrocarbon group represented by L¹¹ may be either saturated or unsaturated, and is preferably saturated. In addition, the chain aliphatic hydrocarbon group represented by L¹¹ may be linear or branched, and is preferably linear.

The chain aliphatic hydrocarbon group represented by L¹¹ is preferably a linear alkylene group, more preferably a linear alkylene group having 1 or more and 5 or less carbon atoms, further preferably a methylene group or an ethylene group, and particularly preferably a methylene group.

L¹ is preferably a single bond, —O—, or —C(═O)—O—, and more preferably a single bond or —C(═O)—O—.

Examples of the divalent linking group represented by Y¹ include a divalent hydrocarbon group having 1 or more and 15 or less carbon atoms which may have a substituent.

The number of carbon atoms of the divalent hydrocarbon group represented by Y¹ which may have a substituent is preferably 1 or more and 12 or less.

The hydrocarbon group represented by Y¹ may be an aliphatic hydrocarbon group, an aromatic hydrocarbon group, or a combination of an aliphatic hydrocarbon group and an aromatic hydrocarbon group.

The aliphatic hydrocarbon group represented by Y¹ may be either a saturated aliphatic hydrocarbon group or an unsaturated aliphatic hydrocarbon group, and is preferably a saturated aliphatic hydrocarbon group.

The aliphatic hydrocarbon group represented by Y¹ may be a chain aliphatic hydrocarbon group, an alicyclic hydrocarbon group, or a combination of a chain aliphatic hydrocarbon group and an alicyclic hydrocarbon group. The chain aliphatic hydrocarbon group contained in the aliphatic hydrocarbon group represented by Y¹ may be linear or branched. As the chain aliphatic hydrocarbon group contained in the aliphatic hydrocarbon group represented by Y¹, an alkylene group is preferable.

The number of carbon atoms of the alkylene group is preferably 1 or more and 10 or less, more preferably 1 or more and 8 or less, and further preferably 1 or more and 5 or less.

Examples of the linear alkylene group include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

Examples of the branched alkylene group include alkylalkylene groups such as: alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 or more and 5 or less carbon atoms.

The chain aliphatic hydrocarbon group may have a substituent. Examples of the substituent include an alkyl group, an alkoxy group, a halogen atom, a halogenated alkyl group, and a hydroxy group. Among these, the hydroxy group is preferable.

In the chain aliphatic hydrocarbon group, at least a part of a methylene group may be substituted with a divalent group other than the methylene group. Examples of the divalent group include —O—, —S—, and —C(═O)—. Among these, the —O— is preferable.

The number of carbon atoms of the alicyclic hydrocarbon group is preferably 3 or more and 20 or less, more preferably 3 or more and 12 or less, and further preferably 5 or more and 12 or less.

The alicyclic hydrocarbon group may be either a monocyclic group or a polycyclic group. A monocyclic aliphatic hydrocarbon group is preferably a group obtained by removing two hydrogen atoms from a monocycloalkane. The number of carbon atoms of the monocycloalkane is preferably 3 or more and 6 or less. Specific examples of the monocycloalkane include cyclopentane and cyclohexane. A polycyclic aliphatic hydrocarbon group is preferably a group obtained by removing two hydrogen atoms from a polycycloalkane. The number of carbon atoms of the polycycloalkane is preferably 7 or more and 12 or less. Specific examples of the polycycloalkane include adamantane, norbornane, isobornane, tricyclodecane, and tetracyclododecane.

The alicyclic hydrocarbon group may have a substituent. Examples of the substituent include an alkyl group, an alkoxy group, a halogen atom, a halogenated alkyl group, and a hydroxy group. Among these, the hydroxy group is preferable. The alkyl group as the substituent is preferably an alkyl group having 1 or more and 5 or less carbon atoms, and more preferably a methyl group, an ethyl group, a propyl group, an n-butyl group, or a tert-butyl group.

The alkoxy group as the substituent is preferably an alkoxy group having 1 or more and 5 or less carbon atoms, more preferably a methoxy group, an ethoxy group, an n-propyloxy group, an isopropyloxy group, an n-butyloxy group, or a tert-butyloxy group, and further preferably a methoxy group or an ethoxy group.

The halogen atom as the substituent is preferably a fluorine atom.

Examples of the halogenated alkyl group as the substituent include groups in which some or all of the hydrogen atoms in the alkyl groups described above are substituted with the halogen atom described above.

In the alicyclic hydrocarbon group, some of the carbon atoms constituting a ring structure thereof may be substituted with a group containing a heteroatom. The group containing a heteroatom is preferably —O—, —C(═O)—O—, —S—, —S(═O)₂—, or —S(═O)₂—O—, and more preferably —O—.

The aromatic hydrocarbon group represented by Y¹ may be a monocyclic aromatic hydrocarbon group or a polycyclic aromatic hydrocarbon group. The polycyclic aromatic hydrocarbon group may be a group in which two or more aromatic rings are condensed with a monocyclic aromatic hydrocarbon group, or may be a group in which a monocyclic aromatic hydrocarbon group or a group in which two or more aromatic rings are condensed with a monocyclic aromatic hydrocarbon group is bonded to one or more aromatic hydrocarbon groups via a single bond. The number of carbon atoms of the aromatic hydrocarbon group is preferably 6 or more and 30 or less, more preferably 6 or more and 20 or less, further preferably 6 or more and 15 or less, and particularly preferably 6 or more and 12 or less.

Examples of the aromatic ring constituting the aromatic hydrocarbon group include a benzene ring, a naphthalene ring, a biphenyl ring, an anthracene ring, and a phenanthrene ring. Among these, a benzene ring and a naphthalene ring are preferable, and a benzene ring is more preferable.

The aromatic hydrocarbon group may have a substituent. Examples of the substituent include an alkyl group, an alkoxy group, a halogen atom, a halogenated alkyl group, and a hydroxy group. The alkyl group, the alkoxy group, the halogen atom, and the halogenated alkyl group as the substituent which the aromatic hydrocarbon group may have are the same as the substituent which the alicyclic hydrocarbon group may have.

As Y¹, a chain aliphatic hydrocarbon group which may have a substituent, an alicyclic hydrocarbon group which may have a substituent, an aromatic hydrocarbon group which may have a substituent, or a combination thereof is preferable, an alkylene group which may have a substituent, an alicyclic hydrocarbon group which may have a substituent, an aromatic hydrocarbon group which may have a substituent, or a combination thereof is more preferable, and an alkylene group which may have a hydroxy group, in which at least a part of the methylene group may be substituted with —O—, an alicyclic hydrocarbon group which may have a hydroxy group, in which a part of the carbon atoms constituting a ring structure may be substituted with —O—, an aromatic hydrocarbon group, or a combination thereof is further preferable.

Specific examples of the constituent unit represented by Formula (a2) are shown below. In the following formulae, R^{a22} represents a hydrogen atom, a methyl group, or a trifluoromethyl group.

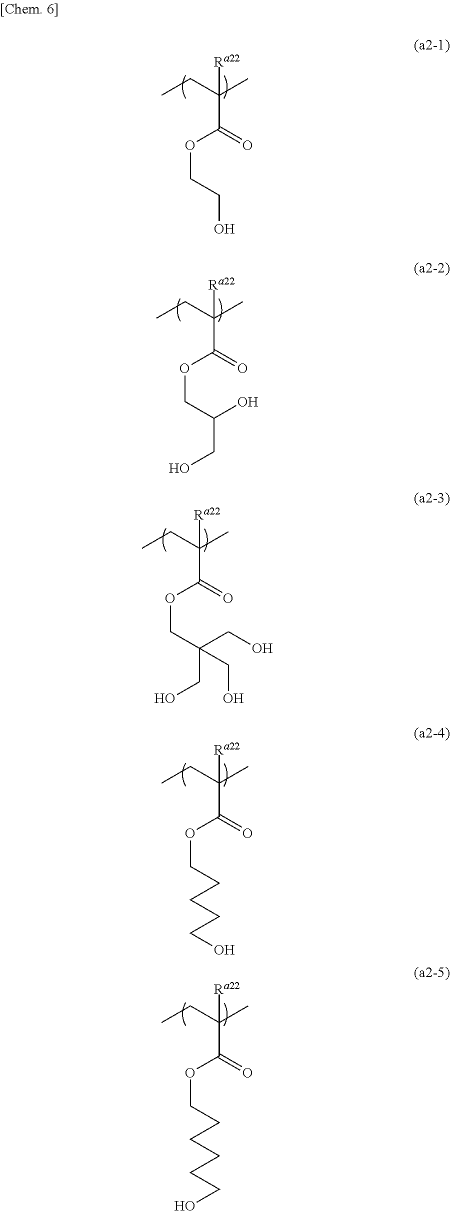

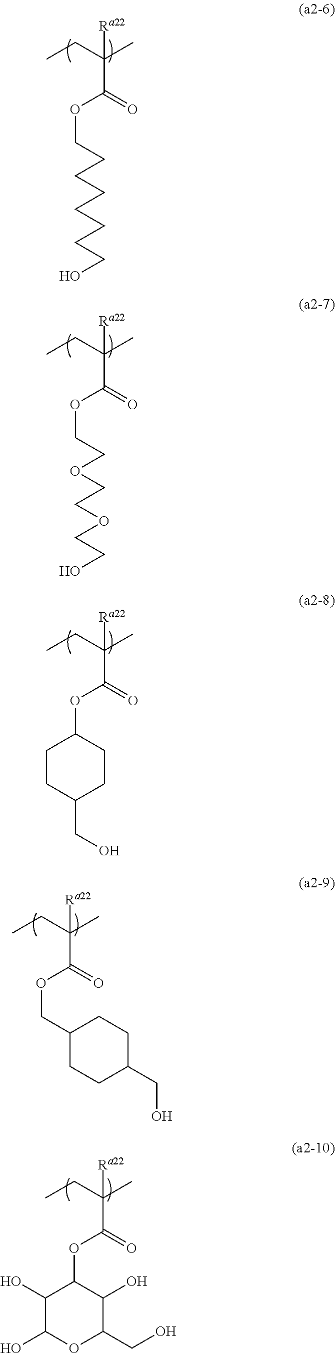

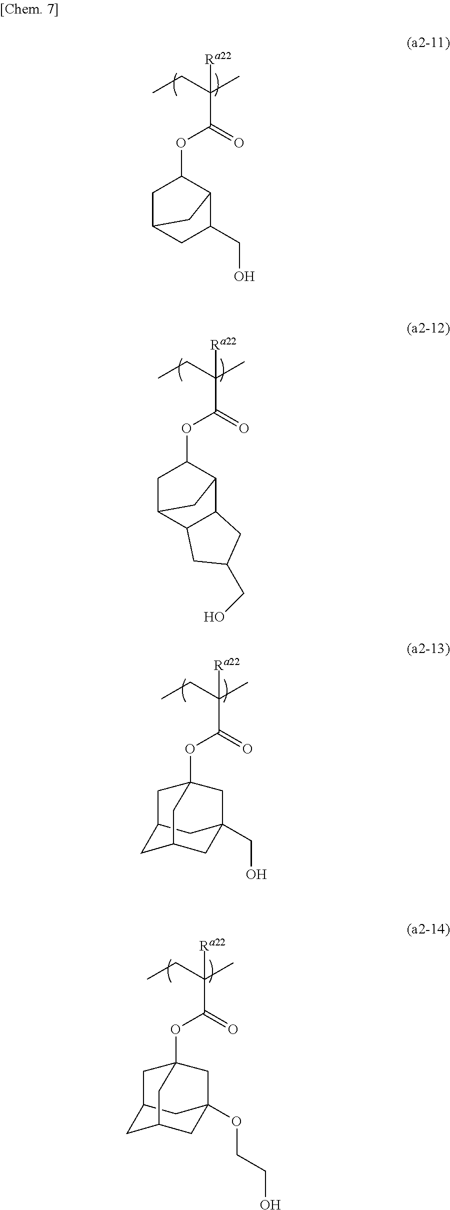

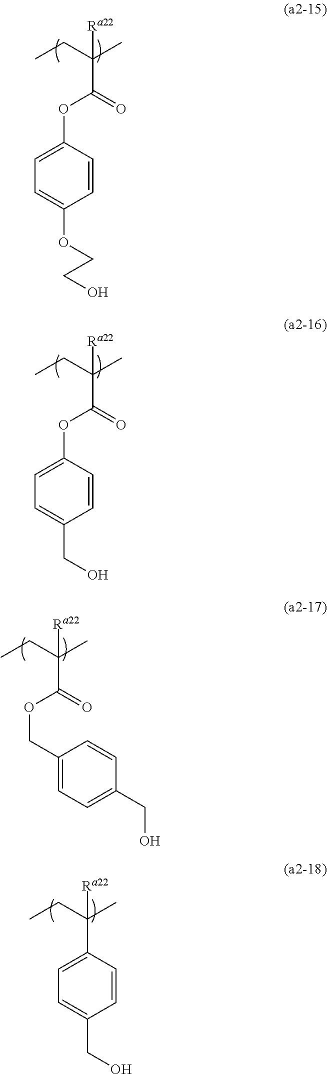

A molar ratio of the constituent unit of the block (A2) to a total of the constituent unit of the block (A1) and the constituent unit of the block (A2) is preferably 1 mol % or more, and more preferably 3 mol % or more. In addition, the above ratio is preferably 35 mol % or less, and more preferably 30 mol % or less. Within the above numerical range, good horizontal orientation is easily obtained.

The molar ratio of the constituent unit of the block (A2) to all the constituent units of the block copolymer (A) is preferably 1 mol % or more, and more preferably 3 mol % or more. In addition, the above ratio is preferably 35 mol % or less, and more preferably 30 mol % or less. Within the above numerical range, good horizontal orientation is easily obtained.

The total molar ratio of the constituent unit of the block (A1) and the constituent unit of the block (A2), regarding all the constituent units of the block copolymer (A), is preferably 70 mol % or more, more preferably 90 mols or more, further preferably 95 mol % or more, and may be 100 mol %.

A number average molecular weight (Mn) of the block copolymer (A) is preferably 500 or more, and more preferably 1,000 or more. In addition, the Mn is preferably 30,000 or less, more preferably 20,000 or less, and further preferably 10,000 or less. Within the above numerical range, good horizontal orientation is easily obtained.

A molecular weight dispersity (Mw/Mn) of the block copolymer (A) is preferably 1.0 or more and 3.0 or less, more preferably 1.0 or more and 1.5 or less, and further preferably 1.0 or more and 1.3 or less. Note that Mw represents a mass average molecular weight.

In the present description, the “number average molecular weight” (Mn) and the “mass average molecular weight” (Mw) refer to a number average molecular weight and a mass average molecular weight in terms of standard polystyrene obtained by gel permeation chromatography (GPC) measurement.

The method for producing a block copolymer (A) is not particularly limited. For example, the block copolymer (A) can be produced by polymerizing a monomer for the constituent unit constituting the block (A1) and a monomer for the constituent unit constituting the block (A2) by a polymerization method known in the related art. In the polymerization, as the monomer for the constituent unit constituting the block (A2), a monomer in which a hydroxy group is protected with a protecting group known in the related art such as a trimethylsilyl group or an acetal structure may be used. In this case, deprotection is performed after the polymerization.

A content of the block copolymer (A) is preferably 70 mass, or more, more preferably 90 mass % or more, further preferably 95 mass % or more, and may be 100 mass % with respect to 100 mass % of a solid content of the base material.

### <Solvent(S)>

The base material may contain a solvent(S).

Examples of the solvent(S) include organic solvents. Any organic solvent may be used as long as the organic solvent can dissolve each component to be used and form a homogeneous solution. In the related art, any organic solvent selected from organic solvents known as a solvent for a composition containing a resin as a main component may be used.

Examples of the organic solvent include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; monoacetate of polyhydric alcohols such as ethylene glycol monoacetate, diethylene glycol monoacetate, propylene glycol monoacetate, or dipropylene glycol monoacetate; derivatives of polyhydric alcohols such as a compound having an ether bond including monoalkyl ethers or monophenyl ethers such as monomethyl ether, monoethyl ether, monopropyl ether, and monobutyl ether of the polyhydric alcohols or the monoacetate of polyhydric alcohols [among these, propylene glycol monomethyl ether acetate (PGMEA) and propylene glycol monomethyl ether (PGME) are preferable]; cyclic ethers such as dioxane, and esters other than the monoacetate of polyhydric alcohols and the derivatives of polyhydric alcohols, such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzyl ether, cresyl methyl ether, diphenylether, dibenzyl ether, phenetol, butyl phenyl ether, ethylbenzene, diethylbenzene, pentylbenzene, isopropylbenzene, toluene, xylene, cymene, and mesitylene. The organic solvent component may be used alone or used as a mixed solvent of two or more thereof. Among these, the propylene glycol monomethyl ether acetate (PGMEA), the propylene glycol monomethyl ether (PGME), cyclohexanone, or the ethyl lactate (EL) is preferable.

A content of the solvent contained in the base material is not particularly limited. The solvent is appropriately set according to a coating film thickness such that the base material has a concentration with which the base material can be applied. The solvent is generally used such that a solid content concentration of the base material is in a range of 0.2 mass % or more and 70 mass % or less, and preferably 0.2 mass % or more and 50 mass % or less.

### <Other Components>

Further, if desired, miscible additives, for example, an additional resin for improving performance of the base material layer, a surfactant for improving coatability, a dissolution inhibiting agent, a plasticizing agent, a stabilizing agent, a coloring agent, an anti-halation agent, a dye, a sensitizing agent, a base proliferating agent, a basic compound, and the like can be appropriately added to the base material.

### (Contact Angle of Water on Surface of Base Material Layer Formed on Substrate)

The base material preferably has a contact angle of water on a surface of the base material layer, when it is formed by baking the base material at 160° C. (hereinafter, also referred to as a “contact angle (160° C.)”) after forming a film of the base material on the substrate, of 80° or more, and more preferably 85° or more.

The base material preferably has a contact angle of water on a surface of the base material layer, when it is formed by baking the base material at 240° C. (hereinafter, also referred to as a “contact angle (240° C.)”) after forming a film of the base material on the substrate, of 80° or more, more preferably 85° or more, and further preferably 88° or more.

The base material preferably has a difference between the contact angle (240° C.) and the contact angle (160° C.) (contact angle (240° C.)—contact angle (160° C.)) of 5.00 or less, and more preferably 3.0° or less.

When the contact angle is within the above numerical range, it is considered that adhesion between the substrate and the layer containing the block copolymer via the base material layer is enhanced. Accordingly, it is considered that phase separation performance of the layer containing the block copolymer formed on the base material layer is enhanced. In addition, when the contact angle (160° C.) is within the above numerical range, it is considered that sufficient phase separation performance can be obtained even when baking is performed at a temperature of 200° C. or lower (for example, 160° C. or higher and 200° C. or lower).

The contact angle of water is measured by, for example, the following procedures, more specifically, procedures described in Examples below.

Procedure (1): A PGMEA solution of the block copolymer (A) is applied onto a substrate and baked at 160° C. or 240° C. for 120 seconds to form a base material layer having a film thickness of 25 nm.

Procedure (2): The base material layer is rinsed to remove a polymer that is not adhered to the substrate.

Procedure (3): 2 μL of water is added dropwise on a surface of the base material layer, and a contact angle (static contact angle) is measured by a contact angle meter.

### <<Method for Producing Structure Having Phase-separated Structure>>

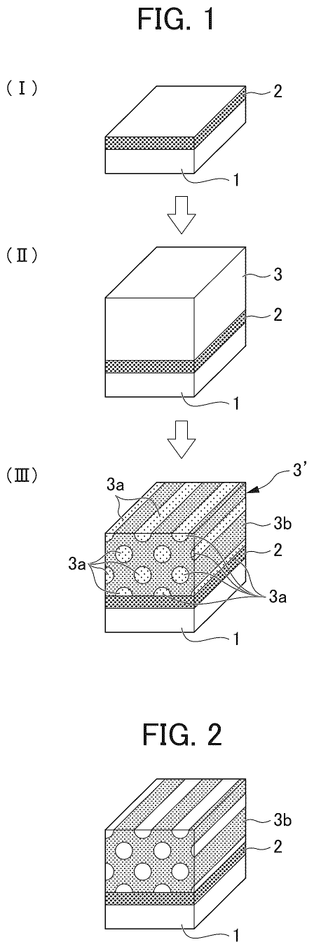

The method for producing a structure including a phase-separated structure includes: applying the base material as described in the first aspect to form a base material layer (hereinafter, also referred to as “step (i)”); forming a layer containing a block copolymer on the base material layer (hereinafter, also referred to as “step (ii)”); and bringing the layer containing the block copolymer to phase separation (hereinafter, also referred to as “step (iii)”). Hereinafter, such a method for producing a structure having a phase-separated structure will be described in detail with reference to FIG. 1. However, the present invention is not limited thereto.

FIG. 1 illustrates an example embodiment of the method for producing a structure having a phase-separated structure. First, a base material is applied onto a substrate 1 to form a base material layer 2 ((I) of FIG. 1; step (i)).

Next, a composition containing a block copolymer (hereinafter, also referred to as a “BCP composition”) is applied onto the base material layer 2 to form a layer 3 containing the block copolymer ((II) of FIG. 1; step (ii)).

Next, an annealing treatment is performed by heating, and the layer 3 containing the block copolymer is brought to phase-separation into a phase 3a and a phase 3b ((III) of FIG. 1; step (iii)).

According to the production method of the present embodiment described above, that is, the production method including the steps (i) to (iii), a structure 3′ including a phase-separated structure is produced on the substrate 1 on which the base material layer 2 is formed.

### [Block Copolymer]

The block copolymer is, for example, a polymer compound in which a hydrophobic polymer block (b11) and a hydrophilic polymer block (b21) are bonded.

The hydrophobic polymer block (b11) (hereinafter, also simply referred to as a “block (b11)”) refers to a block formed of a polymer (hydrophobic polymer) obtained by polymerizing a monomer having a relatively low affinity for water. The hydrophilic polymer block (b21) (hereinafter, also simply referred to as “block (b21)”) refers to a block formed of a polymer (hydrophilic polymer) obtained by polymerizing a monomer having a relatively high affinity for water.

The block (b11) and the block (b21) are not particularly limited as long as the combination of the blocks causes phase separation, which combination is preferably a combination of blocks incompatible with each other.

In addition, the combination of the block (b11) and the block (b21) is preferably such a combination that at least one block among a plurality of blocks of the block copolymer forms a phase that can be more easily removed than a phase formed of other blocks.

The number of types of blocks constituting the block copolymer may be two or three or more. In the block copolymer, a partial constituent component (block) other than the block (b11) and the block (b21) may be bonded.

Examples of the block (b11) and the block (b21) include a block in which a constituent unit derived from styrene or a styrene derivative is repeatedly bonded; a block in which a constituent unit derived from an acrylic acid ester in which a hydrogen atom bonded to a carbon atom at an α-position may be substituted with a substituent (a constituent unit derived from an (α-substituted) acrylic acid ester) is repeatedly bonded; a block in which a constituent unit derived from acrylic acid in which a hydrogen atom bonded to a carbon atom at an α-position may be substituted with a substituent (a constituent unit derived from (α-substituted) acrylic acid) is repeatedly bonded; a block in which a constituent unit derived from siloxane or a derivative thereof is repeatedly bonded; a block in which a constituent unit derived from an alkylene oxide is repeatedly bonded; and a block in which a silsesquioxane structure-containing constituent unit is repeatedly bonded.

Examples of the styrene derivative include compounds in which a hydrogen atom bonded to a carbon atom at an α-position of styrene is substituted with a substituent such as an alkyl group having 1 or more and 10 or less carbon atoms; and compounds in which a hydrogen atom of a phenyl group of styrene is substituted with a substituent such as an alkyl group having 1 or more and 10 or less carbon atoms, an alkoxy group having 1 or more and 10 or less carbon atoms, a hydroxy group, a nitro group, a halogen atom, and an acetoxy group. Specific examples of the styrene derivative include α-methylstyrene, 2-methylstyrene, 3-methylstyrene, 4-methylstyrene, 4-tert-butylstyrene, 4-n-octylstyrene, 2, 4, 6-trimethylstyrene, 4-methoxystyrene, 4-tert-butoxystyrene, 4-hydroxystyrene, 4-nitrostyrene, 3-nitrostyrene, 4-chlorostyrene, 4-fluorostyrene, 4-acetoxystyrene, and 4-chloromethylstyrene.

The (α-substituted) acrylic acid ester is an acrylic acid derivative in which an acrylic acid ester or a hydrogen atom bonded to a carbon atom at an α-position of the acrylic acid ester is substituted with a substituent.

Examples of the substituent in the (α-substituted) acrylic acid ester include an alkyl group having 1 or more and 5 or less carbon atoms and a halogenated alkyl group having 1 or more and 5 or less carbon atoms. Among these, an alkyl group having 1 or more and 5 or less carbon atoms is preferable, and a methyl group is more preferable.

Suitable examples of the (α-substituted) acrylic acid ester include an (α-substituted) acrylic acid alkyl ester, an (α-substituted) acrylic acid cycloalkyl ester, an (α-substituted) acrylic acid hydroxyalkyl ester, an (α-substituted) acrylic acid aryl ester, an (α-substituted) acrylic acid aralkyl ester, an (α-substituted) acrylic acid epoxyalkyl ester, and an (α-substituted) acrylic acid epoxycycloalkylalkyl ester.

Among these (α-substituted) acrylic acid esters, the (α-substituted) acrylic acid alkyl ester is preferable. In the (α-substituted) acrylic acid alkyl ester, the number of carbon atoms of an alkyl group constituting an alkyl ester is preferably 1 or more and 10 or less, and more preferably 1 or more and 5 or less.

Specific examples of the (α-substituted) acrylic acid ester include acrylic acid esters such as methyl acrylate, ethyl acrylate, propyl acrylate, n-butyl acrylate, tert-butyl acrylate, cyclohexyl acrylate, octyl acrylate, nonyl acrylate, hydroxyethyl acrylate, hydroxypropyl acrylate, benzyl acrylate, anthryl acrylate, glycidyl acrylate, 3,4-epoxycyclohexylmethyl acrylate, and 3-trimethoxysilylpropyl acrylate; and methacrylic acid esters such as methyl methacrylate, ethyl methacrylate, propyl methacrylate, n-butyl methacrylate, tert-butyl methacrylate, cyclohexyl methacrylate, octyl methacrylate, nonyl methacrylate, hydroxyethyl methacrylate, hydroxypropyl methacrylate, benzyl methacrylate, anthryl methacrylate, glycidyl methacrylate, 3, 4-epoxycyclohexylmethyl methacrylate, and 3-trimethoxysilylpropyl methacrylate.

Among the above, the (α-substituted) acrylic acid ester is preferably the acrylic acid alkyl ester or a methacrylic acid alkyl ester, more preferably the methyl acrylate, the ethyl acrylate, the tert-butyl acrylate, the methyl methacrylate, the ethyl methacrylate, or the tert-butyl methacrylate, and further preferably the methyl methacrylate.

Examples of the (α-substituted) acrylic acid include acrylic acid and acrylic acid in which a hydrogen atom bonded to a carbon atom at an α-position is substituted with a substituent. Examples of the substituent include an alkyl group having 1 or more and 5 or less carbon atoms, a halogenated alkyl group having 1 or more and 5 or less carbon atoms, and a hydroxyalkyl group. Specific examples of the (α-substituted) acrylic acid include acrylic acid and methacrylic acid.

Examples of the siloxane or a derivative thereof include dimethylsiloxane, diethylsiloxane, diphenylsiloxane, and methylphenylsiloxane.

Examples of the alkylene oxide include ethylene oxide, propylene oxide, isopropylene oxide, and butylene oxide.

The silsesquioxane structure-containing constituent unit is preferably a cage silsesquioxane structure-containing constituent unit. Examples of a monomer providing the cage silsesquioxane structure-containing constituent unit include a compound having a cage silsesquioxane structure and a polymerizable group.

Examples of the block copolymer include a polymer compound in which a block in which a constituent unit derived from styrene or a styrene derivative is repeatedly bonded and a block in which a constituent unit derived from an (xa-substituted) acrylic acid ester is repeatedly bonded are bonded; a polymer compound in which a block in which a constituent unit derived from styrene or a styrene derivative is repeatedly bonded and a block in which a constituent unit derived from (α-substituted) acrylic acid is repeatedly bonded are bonded; a polymer compound in which a block in which a constituent unit derived from styrene or a styrene derivative is repeatedly bonded and a block in which a constituent unit derived from siloxane or a derivative thereof is repeatedly bonded are bonded; a polymer compound in which a block in which a constituent unit derived from an alkylene oxide is repeatedly bonded and a block in which a constituent unit derived from an (α-substituted) acrylic acid ester is repeatedly bonded; a polymer compound in which a block in which a constituent unit derived from an alkylene oxide is repeatedly bonded and a block in which a constituent unit derived from (α-substituted) acrylic acid is repeatedly bonded are bonded; a polymer compound in which a block in which a cage silsesquioxane structure-containing constituent unit is repeatedly bonded and a block in which a constituent unit derived from an (α-substituted) acrylic acid ester is repeatedly bonded are bonded; a polymer compound in which a block in which a cage silsesquioxane structure-containing constituent unit is repeatedly bonded and a block in which a constituent unit derived from (α-substituted) acrylic acid is repeatedly bonded are bonded; and a polymer compound in which a block in which a cage silsesquioxane structure-containing constituent unit is repeatedly bonded and a block in which a constituent unit derived from siloxane or a derivative thereof are repeatedly bonded are bonded.

Among the above, the block copolymer is preferably the polymer compound in which a block in which a constituent unit derived from styrene or a styrene derivative is repeatedly bonded and a block in which a constituent unit derived from an (α-substituted) acrylic acid ester is repeatedly bonded are bonded and the polymer compound in which a block in which a constituent unit derived from styrene or a styrene derivative is repeatedly bonded and a block in which a constituent unit derived from (α-substituted) acrylic acid is repeatedly bonded are bonded, more preferably the polymer compound in which a block in which a constituent unit derived from styrene or a styrene derivative is repeatedly bonded and a block in which a constituent unit derived from an (α-substituted) acrylic acid ester is repeatedly bonded are bonded, and further preferably a polymer compound in which a block in which a constituent unit derived from styrene or a styrene derivative is repeatedly bonded and a block in which a constituent unit derived from a (meth)acrylic acid ester is repeatedly bonded are bonded.

Specific examples thereof include a polystyrene-polymethyl methacrylate (PS-PMMA) block copolymer, a polystyrene-polyethyl methacrylate block copolymer, a polystyrene-(poly-t-butyl methacrylate) block copolymer, a polystyrene-polymethacrylate block copolymer, a polystyrene-polymethyl acrylate block copolymer, a polystyrene-polyethyl acrylate block copolymer, a polystyrene-(poly-t-butyl acrylate) block copolymer, and a polystyrene-polyacrylic acid block copolymer. Among these, the PS-PMMA block copolymer is particularly preferable.

A number average molecular weight (Mn) of the block copolymer is not particularly limited as long as the block copolymer has a size capable of causing phase separation, and is preferably 5,000 or more and 500,000 or less, more preferably 30,000 or more and 300,000 or less, and further preferably 50,000 or more and 200,000 or less.

A molecular weight dispersity (Mw/Mn) of the block copolymer is preferably 1.0 or more and 3.0 or less, more preferably 1.0 or more and 1.5 or less, and further preferably 1.0 or more and 1.2 or less.

A period (L0) of a structure including a phase-separated structure produced using the block copolymer is not particularly limited, and is preferably 5 nm or more and 100 nm or less, more preferably 10 nm or more and 80 nm or less, and further preferably 20 nm or more and 70 nm or less. In the base material of the first aspect, the period may be, for example, 45 nm or more or 50 nm or more from the viewpoint of being capable of forming a phase-separated structure having good horizontal orientation even when the period of the structure is relatively large.

In the present description, the phrase “period of the structure” means a period of a phase structure observed when a structure having a phase-separated structure is formed and refers to a sum of lengths of phases incompatible with each other. In a case where the phase-separated structure forms a cylinder structure perpendicular to a surface of a substrate, the period (L0) of the structure is a distance (pitch) between centers of two adjacent cylinder structures.

[Step (i)]

In step (i), the base material is applied onto the substrate 1 to form the base material layer 2. By providing the base material layer 2 on the substrate 1, a hydrophilic-hydrophobic balance between a surface of the substrate 1 and the layer 3 containing the block copolymer can be achieved. That is, the block copolymer (A) contained in the base material used for the base material layer 2 enhances adhesion between the substrate 1 and the phase formed of the hydrophobic polymer block (b11) in the layer 3 containing the block copolymer. Accordingly, it is considered that a phase-separated structure oriented in a horizontal direction with respect to the surface of the substrate 1 is easily formed.

A type of the substrate 1 is not particularly limited as long as the base material can be applied onto the surface of the substrate 1. Examples thereof include a substrate made of silicon, a metal (copper, chromium, iron, aluminum, or the like), and an inorganic material such as glass, titanium oxide, silica, or mica; a substrate made of an oxide such as SiO₂; a substrate made of a nitride such as SiN; a substrate made of an oxynitride such as SiON; and a substrate made of an organic material such as acryl resin, polystyrene, cellulose, cellulose acetate, and a phenolic resin. Among these, a silicon substrate (Si substrate) or a metal substrate is suitable, a Si substrate or a copper substrate (Cu substrate) is more suitable, and a Si substrate is particularly suitable.

A size or a shape of the substrate 1 is not particularly limited. The substrate 1 does not necessarily have a smooth surface, and substrates having various shapes can be appropriately selected. For example, a substrate having a curved surface, a flat plate having an uneven surface, or a substrate having a flaky shape may be used.

An inorganic and/or organic film may be provided on the surface of the substrate 1.

Examples of the inorganic film include an inorganic antireflection film (inorganic BARC).

Examples of the organic film include an organic antireflection film (organic BARC).

The inorganic film can be formed, for example, by applying an inorganic antireflection film composition such as a silicon-based material on a substrate and baking the composition. The organic film can be formed, for example, by applying, on a substrate using a spinner or the like, a material for forming an organic film in which a resin component or the like constituting the organic film is dissolved in an organic solvent, and baking the material under heating conditions of preferably 200° C. or higher and 300° C. or lower for preferably 30 seconds or more and 300 seconds or less, and more preferably for 60 seconds or more and 180 seconds or less. This material for forming an organic film does not necessarily need sensitivity to light or electron beams like a resist film, and may or may not have the sensitivity. Specifically, a resist or a resin generally used for producing a semiconductor element or a liquid crystal display element may be used.

In addition, the material for forming an organic film is preferably a material capable of forming an organic film that can be subjected to etching, particularly dry-etching such that an organic film pattern may be formed by etching the organic film using a pattern formed by processing an upper layer film and made of a block copolymer and transferring the pattern to the organic film. Among these, a material capable of forming an organic film that can be subjected to etching such as oxygen plasma etching is preferable. Such a material for forming an organic film may be a material used for forming an organic film such as an organic BARC in the related art. Examples thereof include ARC series manufactured by Nissan Chemical Corporation, AR series manufactured by Rohm and Haas Japan Ltd., and SWK series manufactured by TOKYO OHKA KOGYO CO., LTD.

A method for forming the base material layer 2 by applying the base material on the substrate 1 is not particularly limited, and the base material layer 2 can be formed by any method known in the related art.

For example, the base material layer 2 can be formed by applying the base material on the substrate 1 by a method known in the related art such as spin coating or using a spinner to form a coated film, and drying the coated film.

A method for drying the coated film is not limited as long as a solvent contained in the base material can be volatilized, and for example, a method for baking may be used. In this case, a baking temperature is preferably 200° C. or lower. In the base material of the first aspect, even when the base material layer 2 is formed by heat treatment at a temperature of 200° C. or lower, sufficient phase separation performance of the BCP composition is obtained. The baking temperature is preferably 150° C. or higher and 200° C. or lower, and more preferably 160° C. or higher and 200° C. or lower. A baking time is preferably 30 seconds or more and 500 seconds or less, more preferably 60 seconds or more and 400 seconds or less, further preferably 100 seconds or more and 300 seconds or less, and still further preferably 100 seconds or more and 200 seconds or less.

The baking time and the baking temperature can be optionally combined.

A thickness of the base material layer 2 after drying the coated film is preferably about 10 nm or more and 100 nm or less, more preferably about 20 nm or more and 90 nm or less, and further preferably about 20 nm or more and 50 nm or less.

The surface of the substrate 1 may be previously washed before the base material layer 2 is formed on the substrate 1. By washing the surface of the substrate 1, coatability of the base material is improved.

As a washing treatment method, a method known in the related art can be used, and examples thereof include an oxygen plasma treatment, an ozone oxidation treatment, an acid alkali treatment, and a chemical modification treatment.

After the base material layer 2 is formed, the base material layer 2 may be rinsed with a rinsing liquid such as a solvent, as necessary. By the rinsing, a polymer or the like having insufficient adhesion to the substrate in the base material layer 2 is removed, so that affinity with at least one polymer (block) constituting the block copolymer is improved, and the phase-separated structure oriented in the horizontal direction with respect to the surface of the substrate 1 is easily formed. The rinsing liquid may be any rinsing liquid capable of dissolving the polymer having insufficient adhesion to the substrate, and a solvent such as propylene glycol monomethyl ether acetate (PGMEA), propylene glycol monomethyl ether (PGME), and ethyl lactate (EL), or a commercially available thinner liquid may be used.

After the washing, post-baking may be performed in order to volatilize the rinsing liquid. A temperature condition of the post-baking is preferably 80° C. or higher and 300° C. or lower, more preferably 100° C. or higher and 250° C. or lower, further preferably 100° C. or higher and 200° C. or lower, and particularly preferably 100° C. or higher and 150° C. or lower. A baking time is preferably 30 seconds or more and 500 seconds or less, and more preferably 60 seconds or more and 240 seconds or less. A thickness of the base material layer 2 after such post-baking is preferably about 1 nm or more and 10 nm or less, and more preferably about 2 nm or more and 7 nm or less.

[Step (ii)]

In step (ii), the layer 3 containing a block copolymer in which a plurality of blocks are bonded is formed on the base material layer 2. As the block copolymer, a block copolymer in which the hydrophobic polymer block (b11) and the hydrophilic polymer block (b21) described above are bonded can be adopted.

A method for forming the layer 3 on the base material layer 2 is not particularly limited, and examples thereof include a method in which a BCP composition is applied onto the base material layer 2 by a method known in the related art such as spin coating or using a spinner to form a coated film, and drying the coated film. Details of such a BCP composition will be described later.

A thickness of the layer 3 may only be sufficient for phase separation to occur. Considering a type of the substrate 1, or a size of a structural period or uniformity of a nanostructure of the phase-separated structure to be formed, or the like, the thickness is preferably 20 nm or more and 100 nm or less, and more preferably 30 nm or more and 80 nm or less.

For example, when the substrate 1 is a Cu substrate, the thickness of the layer 3 is preferably 10 nm or more and 100 nm or less, and more preferably 30 nm or more and 80 nm or less.

[Step (iii)]

In the step (iii), the layer 3 containing a block copolymer is brought to phase separation. By subjecting the substrate 1 after the step (ii) to an annealing treatment by heating, a phase-separated structure is formed in which at least a portion of the surface of the substrate 1 is exposed by selective removal of the block copolymer. That is, the structure 3′ (FIG. 1 (III)) is produced on the substrate 1 to have a phase-separated structure formed by phase-separation into the phase 3a and the phase 3b.

A temperature condition of the annealing treatment is preferably that the annealing treatment is performed at a temperature equal to or higher than a glass transition temperature of the block copolymer used and lower than a thermal decomposition temperature. For example, when the block copolymer is a polystyrene-polymethyl methacrylate (PS-PMMA) block copolymer (weight average molecular weight: 5,000 or more and 100,000 or less), the temperature condition is preferably 180° C. or higher and 290° C. or lower. A heating time is preferably 30 seconds or more and 3, 600 seconds or less.

The annealing treatment is preferably performed in a less reactive gas such as nitrogen.

### [Optional Step]

The method for producing a structure having a phase-separated structure is not limited to the embodiment described above and may include a step (optional step) other than the steps (i) to (iii).

Such an optional step includes a step of selectively removing a phase formed of at least one block among the plurality of blocks constituting the block copolymer from the layer containing the block copolymer (hereinafter, referred to as “step (iv)”), a guide pattern forming step, and the like.

### Regarding Step (iv)

In the step (iv), the phase formed of at least one block among the plurality of blocks constituting the block copolymer is selectively removed from the layer containing the block copolymer formed on the base material layer. As a result, a fine pattern (polymer nanostructure) is formed.

Examples of the method for selectively removing the phase formed of the block include a method for subjecting the layer containing the block copolymer to an oxygen plasma treatment and a method for subjecting the layer to a hydrogen plasma treatment.

Hereinafter, among the blocks constituting the block copolymer, a block which is not selectively removed is referred to as a block PA, and a block which is selectively removed is referred to as a block PB. For example, after a layer containing the PS-PMMA block copolymer is phase-separated, the layer is subjected to an oxygen plasma treatment, a hydrogen plasma treatment, or the like, whereby the phase formed of the PMMA is selectively removed. In this case, a PS portion is the block PA and a PMMA portion is the block PB.

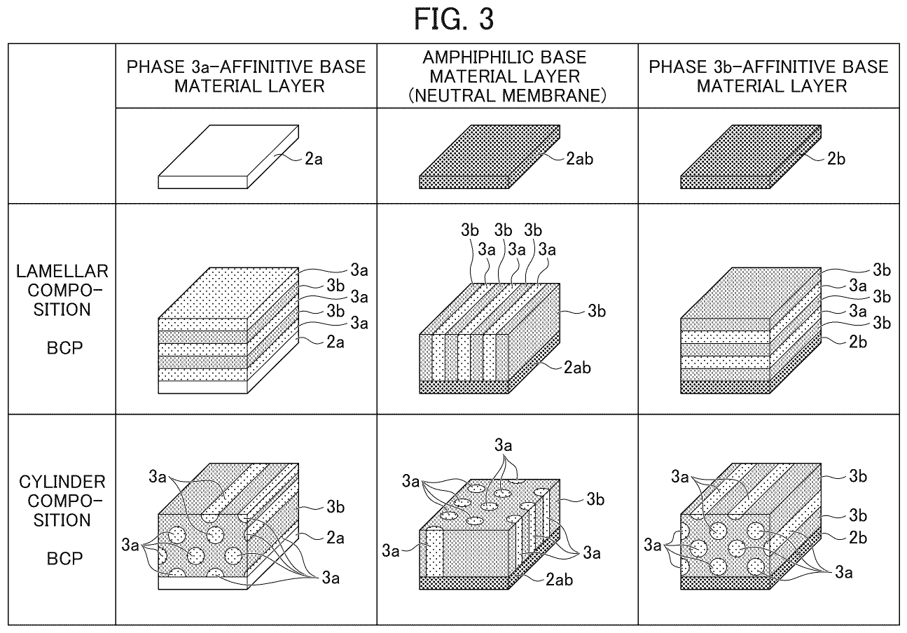

FIG. 2 illustrates an example embodiment of the step (iv). In the embodiment illustrated in FIG. 2, the structure 3′ produced on the substrate 1 in the step (iii) is subjected to an oxygen plasma treatment to selectively remove the phases 3a, resulting in formation of a pattern (polymer nanostructure) constituted by phases 3b apart from each other. In this case, the phase 3b is a phase formed of the block PA, and the phase 3a is a phase formed of the block PB.

The substrate 1 with a pattern formed by phase separation of the layer 3 formed of the block copolymer as described above can be directly used, or a shape of the pattern (polymer nanostructure) on the substrate 1 can be changed by further heating.

A temperature condition during the heating is preferably equal to or higher than a glass transition temperature of the block copolymer used and lower than a thermal decomposition temperature. The heating is preferably performed in a less reactive gas such as nitrogen.

### Regarding Guide Pattern Formation Step

The method for producing a structure having a phase-separated structure may include a step of providing a guide pattern on the base material layer (guide pattern formation step) between the step (i) and the step (ii). This allows an oriented structure of the phase-separated structure to be controlled.

For example, even in the case of a block copolymer from which a random fingerprint-shaped phase-separated structure is formed when a guide pattern is not provided, a groove structure of a resist film can be provided on a surface of the base material layer to obtain a phase-separated structure oriented along the groove. According to this principle, a guide pattern may be provided on the base material layer 2.

The guide pattern can be formed using, for example, a resist composition. For the resist composition for forming the guide pattern, a resist composition having affinity with any of polymers constituting the block copolymer can be appropriately selected from a resist composition to be generally used for forming a resist pattern or a modified product thereof. The resist composition may be either a positive-type resist composition that forms a positive-type pattern in which an exposed area of a resist film is dissolved and removed, or a negative-type resist composition that forms a negative-type pattern in which an unexposed area of a resist film is dissolved and removed, but the negative-type resist composition is preferred. The negative-type resist composition is preferably a resist composition that contains, for example, an acid-generating agent and a base material component having solubility in an organic solvent-containing developing solution that is reduced under an action of an acid, the base material component containing a resin component that has a constituent unit degraded under the action of an acid to have an increased polarity.

After a BCP composition is poured onto the base material layer on which the guide pattern is formed, an annealing treatment is performed to cause phase separation. Therefore, a resist composition capable of forming a resist film having excellent solvent resistance and heat resistance is preferably used as the resist composition for forming the guide pattern.

### Regarding Composition Containing Block Copolymer (BCP Composition)

The BCP composition can be prepared by dissolving the block copolymer described above in an organic solvent. Examples of the organic solvent include the same solvents as the organic solvent in the solvent(S) that can be used for the base material.

The organic solvent contained in the BCP composition is not particularly limited, is appropriately set according to a coating film thickness at a concentration at which coating is possible, and is generally used such that a solid content concentration of the block copolymer is in a range of 0.2 mass % or more and 70 mass % or less, and preferably 0.2 mass % or more and 50 mass % or less.

Further, if desired, the BCP composition may appropriately contain, in addition to the block copolymer and the organic solvent described above, miscible additives such as an additional resin for improving performance of the base material layer, a surfactant for improving coatability, a dissolution inhibiting agent, a plasticizing agent, a stabilizing agent, a coloring agent, an anti-halation agent, a dye, a sensitizing agent, a base proliferating agent, a basic compound, and the like.

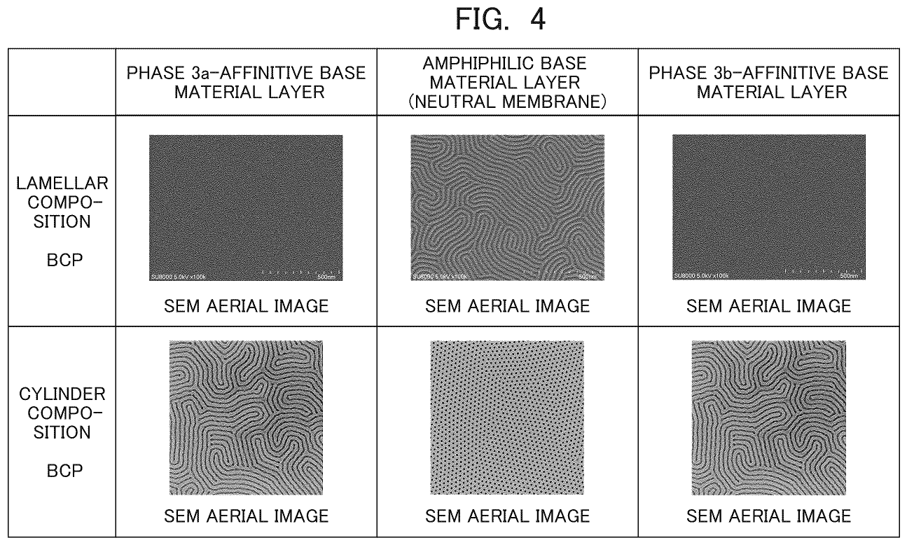

FIG. 3 is a diagram schematically illustrating an example of a structure including a phase-separated structure, which is produced by a production method according to the present embodiment. In FIG. 3, a “lamellar composition BCP” is a case where a block copolymer forming a lamellar phase-separated structure is used. A “cylinder composition BCP” is a case where a block copolymer forming a cylinder phase-separated structure is used. By adjusting a composition of the block copolymer (molecular weight, molar ratio, and the like of each block), the lamellar composition BCP or the cylinder composition BCP can be obtained.

For example, in a case where the base material of the first aspect has affinity for the polymer block constituting the phase 3a, a phase 3a-affinitive base material layer 2a is formed by the step (i) (left column upper row of FIG. 3). Next, when a phase-separated structure is formed by the step (ii) and the step (iii), a lamellar structure (left column center row of FIG. 3) or a cylinder structure (left column lower row of FIG. 3) can be formed according to the composition of the block copolymer. The lamellar structure is a horizontal lamellar structure in which the phase 3a is present in contact with the phase 3a-affinitive base material layer 2a. The cylinder structure is a horizontal cylinder structure in which a cylinder of the phase 3a is present in contact with the phase 3a-affinitive base material layer 2a.

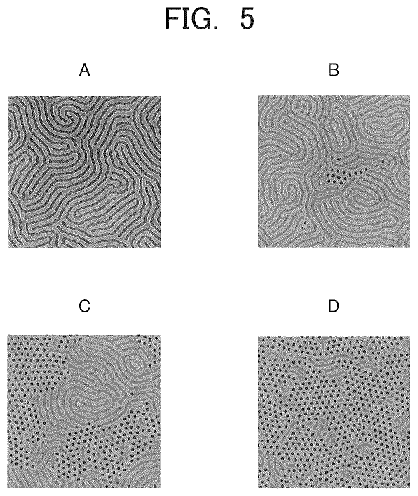

The left column upper row of FIG. 4 is an example of a SEM aerial image of a horizontal lamellar phase-separated structure formed using the phase 3a-affinitive base material layer 2a. Since a horizontal lamella has a structure in which the phase 3a and the phase 3b are repeatedly laminated horizontally, no pattern is observed in the SEM aerial image.

The left column lower row of FIG. 4 is an example of a SEM aerial image of a horizontal cylinder phase-separated structure formed using the phase 3a-affinitive base material layer 2a. Since a guide pattern is not used, a horizontal cylinder (transverse cylinder) has a wavy shape.

For example, in a case where the base material of the first aspect has affinity for the polymer block constituting the phase 3b, a phase 3b-affinitive base material layer 2b is formed by the step (i) (right column upper row of FIG. 3). Next, when a phase-separated structure is formed by the step (ii) and the step (iii), a lamellar structure (right column center row of FIG. 3) or a cylinder structure (right column lower row of FIG. 3) can be formed according to the composition of the block copolymer. The lamellar structure is a horizontal lamellar structure in which the phase 3b is present in contact with the phase 3b-affinitive base material layer 2b. The cylinder structure is a horizontal cylinder structure in which the cylinder of the phase 3a is present not in contact with the phase 3b-affinitive base material layer 2a.

The right column upper row of FIG. 4 is an example of a SEM aerial image of a horizontal lamellar phase-separated structure formed using the phase 3b-affinitive base material layer 2b. Since a horizontal lamella has a structure in which the phase 3b and the phase 3a are repeatedly laminated horizontally, no pattern is observed in the SEM aerial image. The right column lower row of FIG. 4 is an example of a SEM aerial image of a horizontal cylinder phase-separated structure formed using the phase 3b-affinitive base material layer 2b. Since a guide pattern is not used, a horizontal cylinder (transverse cylinder) has a wavy shape.

For example, in a case where the base material has affinity for the polymer blocks of both the phase 3a and the phase 3b, an amphiphilic base material layer 2ab is formed by the step (i) (center column upper row). Next, when a phase-separated structure is formed by the step (ii) and the step (iii), a lamellar structure (center column center row) or a cylinder structure (center column lower row) can be formed according to the composition of the block copolymer. The lamellar structure is a perpendicular lamellar structure in which a repeating structure of the phase 3a and the phase 3b is formed perpendicular to the amphiphilic base material layer 2ab. The cylinder structure is a perpendicular cylinder structure in which the cylinder of the phase 3a is formed perpendicular to the amphiphilic base material layer 2ab.

The center column upper row of FIG. 4 is an example of a SEM aerial image of a perpendicular lamellar phase-separated structure formed by using the amphiphilic base material layer 2ab. Since a guide pattern is not used, a perpendicular lamella in a wavy state (fingerprint) is observed. The center column lower row of FIG. 4 is an example of a SEM aerial image of a perpendicular cylinder phase-separated structure formed by using the amphiphilic base material layer 2ab. Since a guide pattern is not used, perpendicular cylinders (vertical cylinder) are randomly arranged.

Examples of the polymer block constituting the phase 3a include the hydrophobic polymer block (b11). Examples of the polymer block constituting the phase 3b include the hydrophilic polymer block (b21). The hydrophobic polymer block (b11) is not particularly limited as long as the hydrophobic polymer block (b11) has relatively low affinity for water with respect to the hydrophilic polymer block (b21), and examples thereof include a block in which a constituent unit derived from styrene or a styrene derivative is repeatedly bonded.

The hydrophilic polymer block (b21) is not particularly limited as long as the hydrophilic polymer block (b21) has relatively high affinity for water with respect to the hydrophobic polymer block (b11), and examples thereof include a block in which a constituent unit derived from an (α-substituted) acrylic acid ester is repeatedly bonded and a block in which a constituent unit derived from (α-substituted) acrylic acid is repeatedly bonded.

The production method of the present embodiment can be suitably used for producing a structure including a phase-separated structure of a horizontal lamellar structure or a horizontal cylinder structure. The base material of the first aspect tends to have high affinity with the hydrophobic polymer block (b11). Therefore, the base material is suitable for producing a structure including the horizontal lamellar phase-separated structure as illustrated in the left column center row of FIG. 3 or the horizontal cylinder phase-separated structure as illustrated in the left column lower row of FIG. 3.

As described above, the present inventors provide the following (1) to (5).

(1) A base material for bringing a block copolymer-containing layer to phase separation, the base material containing:
a block copolymer (A) including a block (A1) and a block (A2),
   the block (A1) having a constituent unit represented by the following Formula (a1),
   the block (A2) having a constituent unit represented by the following Formula (a2),
the block copolymer (A) having no constituent unit derived from an alkyl (meth)acrylate,
the block copolymer (A) having a molar ratio of the constituent unit of the block (A2) of more than 0 mol % and 40 mol % or less with respect to a total of the constituent unit of the block (A1) and the constituent unit of the block (A2),

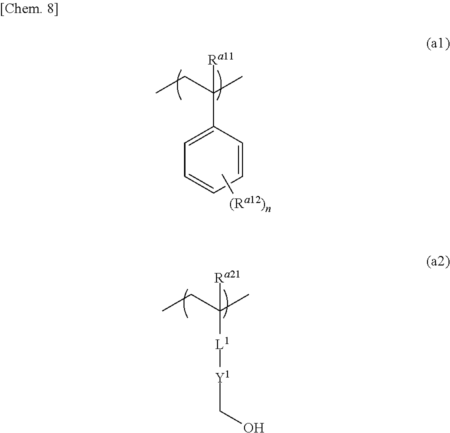

wherein R^{a11} represents a hydrogen atom, an alkyl group having 1 or more and 5 or less carbon atoms, or a halogenated alkyl group having 1 or more and 5 or less carbon atoms, R^{a12} represents a substituent, and n is an integer of 0 or more and 5 or less, and
wherein R^{a21} represents a hydrogen atom, an alkyl group having 1 or more and 5 or less carbon atoms, or a halogenated alkyl group having 1 or more and 5 or less carbon atoms, L¹ represents a single bond or a divalent linking group, and Y¹ represents a divalent linking group having 1 or more and 15 or less carbon atoms.

(2) The base material as described in aspect (1), in which the block copolymer (A) includes no block other than the block (A1) and the block (A2).
(3) The base material as described in aspect (1) or (2), in which the R^{a12} represents an alkyl group having 1 or more and 5 or less carbon atoms,
the L¹ represents a single bond or —C(═O)—O—, and
the Y¹ represents a divalent hydrocarbon group having 1 or more and 15 or less carbon atoms that may have a substituent. (4) The base material as described in any one of aspects (1) to (3), in which the molar ratio of the constituent unit of the block (A2) is 3 mol % or more and 35 mol % or less with respect to the total of the constituent unit of the block (A1) and the constituent unit of the block (A2).

(5) A method for producing a structure including a phase-separated structure, the method including:
applying the base material as described in any one of aspects (1) to (4) onto a substrate to form a base material layer;
forming a block copolymer-containing layer on the base material layer; and
bringing the block copolymer-containing layer to phase separation.

### EXAMPLES

Although the present invention will be described in more detail with reference to Examples, the present invention is not limited to these Examples.

### <Synthesis of Block Copolymer Used for Base Material>

### [Synthesis of Block Copolymer (P-1)]

Under an argon atmosphere, 2.06 g (48.7 mmol) of LiCl and 162 g of tetrahydrofuran (THF) were charged into a Schlenk flask and cooled to −78° C. After the inside of the flask was dehydrated and degassed, 13.2 mL (1.23 mol/L hexane-cyclohexane mixed solution, 16.2 mmol) of sec-butyllithium as an anionic polymerization initiating agent and subsequently 22.1 mL (192 mmol) of a compound (A′-1) were charged into the flask under an argon atmosphere, and stirred at −78° C. for 30 minutes. Next, 4.3 mL (24.3 mmol) of 1,1-diphenylethylene (DPE) was charged into the flask and stirred at −78° C. for 60 minutes. Subsequently, 9.0 mL (42.4 mmol) of a compound (B′-1) was charged into the flask and stirred at −78° C. for 180 minutes. Further, 1 mL (25 mmol) of methanol as a polymerization terminating agent was charged into the flask at −78° C. to stop the reaction, thereby obtaining a reaction polymerization solution.

Into the reaction polymerization solution, 50 mL of 5% hydrochloric acid was charged and stirred at room temperature for 120 minutes. Next, the reaction polymerization solution was added dropwise to a large amount of methanol to precipitate a polymer. A precipitated white powder was collected by filtration and dissolved in 114 g of THE. Into the THE solution, 50 mL of 5% hydrochloric acid was charged and stirred at room temperature for 60 minutes. Subsequently, the THE solution was added dropwise to a large amount of methanol to precipitate a polymer. A precipitated white powder was washed with a large amount of methanol, then washed with a large amount of pure water, and then dried to obtain 21.5 g (yield: 75.4%) of a block copolymer (P-1).

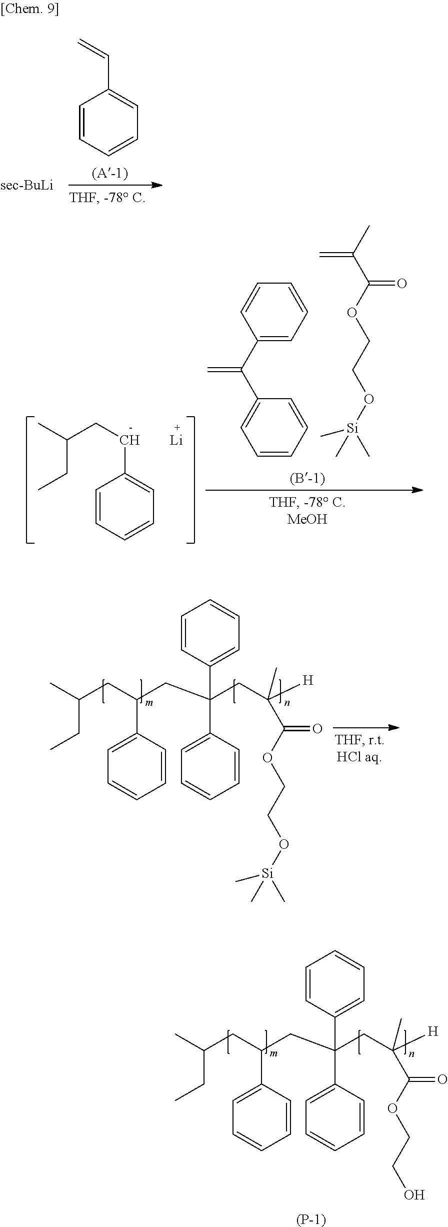

### [Synthesis of Block Copolymers (P-2) to (P-18)]

Using a compound (A′-1) or (A′-2) represented by the following formula and any one of compounds (B′-1) to (B′-9) represented by the following formulae in which a hydroxy group was protected by a trimethylsilyl group or an acetal structure, block copolymers (P-2) to (P-18) having a constituent unit represented by the following formula (A-1) or (A-2) and a constituent unit represented by any one of the following formulae (B-1) to (B-9) were synthesized by a method including polymerization of each compound and elimination of a protecting group in the same manner as in the synthesis of the block copolymer (P-1).

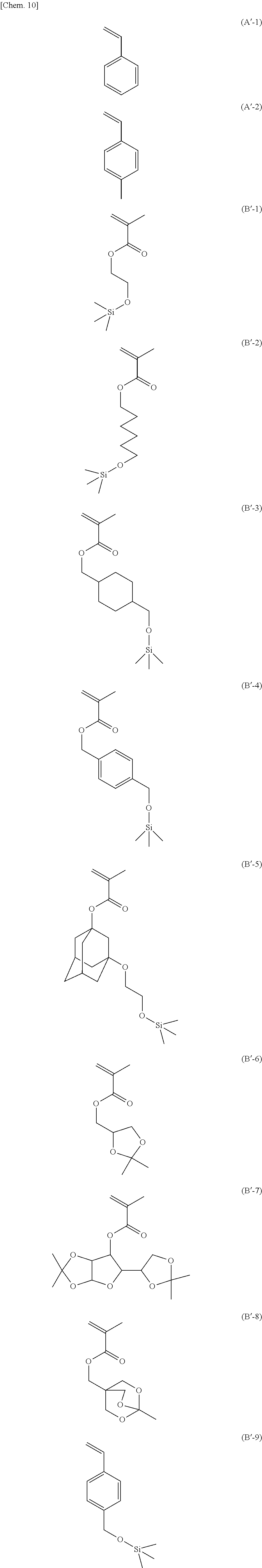

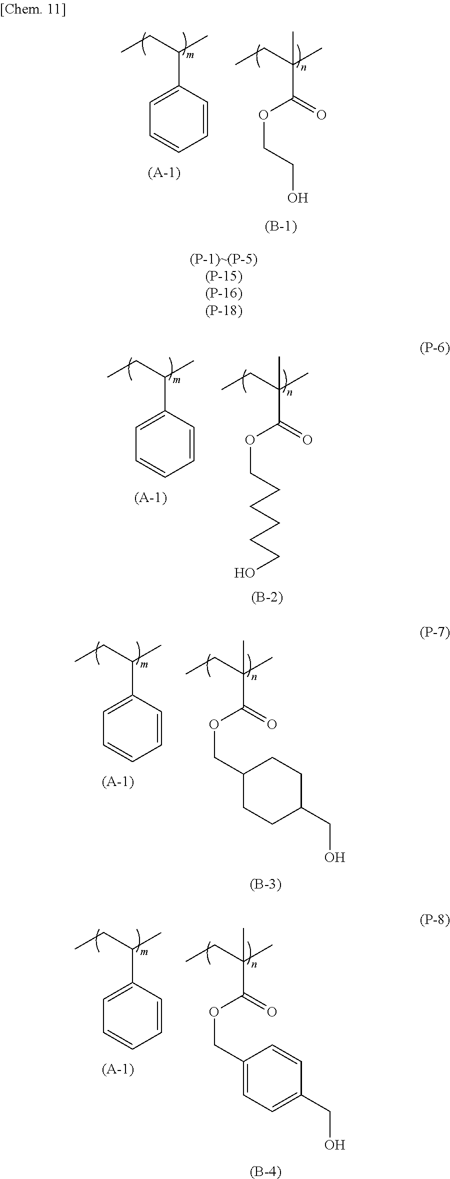

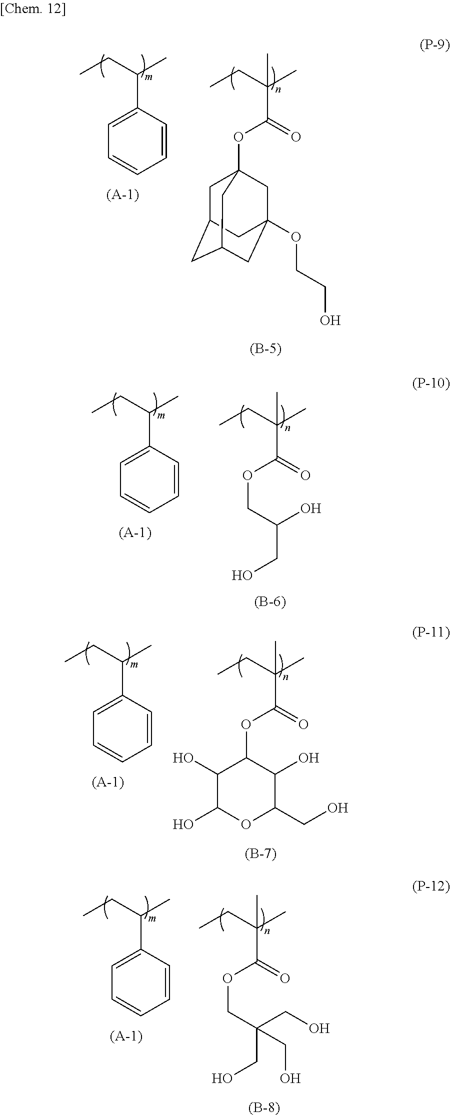

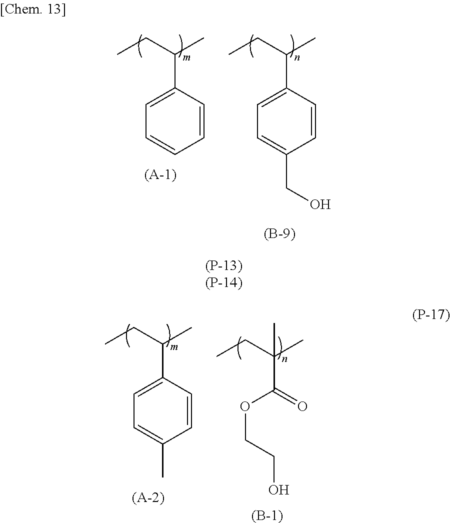

Structures of the block copolymers (P-1) to (P-18) were confirmed by ¹³C-NMR.

Polymers (P-1) to (P-5), (P-15), (P-16), and (P-18) ¹³C-NMR (600 MHZ, CDCl₃): 20 ppm to 22 ppm (α-CH₃), 40 ppm to 50 ppm (backbone), 63 ppm (CH₂OH), 70 ppm (OCH₂), 125 ppm to 131 ppm (Ar, CH), 141 ppm to 145 ppm (Ar, C), 178 ppm (C═O)

### Polymer (P-6)

¹³C-NMR (600 MHZ, CDCl₃): 20 ppm to 22 ppm (α-CH₃), 24 ppm to 35 ppm (CH₂), 40 ppm to 50 ppm (backbone), 63 ppm (CH₂OH), 67 ppm (OCH₂), 125 ppm to 131 ppm (Ar, CH), 140 ppm to 144 ppm (Ar, C), 174 ppm (C═O)

### Polymer (P-7)

¹³C-NMR (600 MHZ, CDCl₃): 20 ppm to 22 ppm (α-CH₃), 24 ppm to 35 ppm (Cy, CH₂. CH), 40 ppm to 50 ppm (backbone), 67 ppm (CH₂OH), 72 ppm (OCH₂), 125 ppm to 131 ppm (Ar, CH), 140 ppm to 144 ppm (Ar, C), 175 ppm (C═O)

### Polymer (P-8)

¹³C-NMR (600 MHZ, CDCl₃): 20 ppm to 22 ppm (α-CH₃), 40 ppm to 50 ppm (backbone), 69 ppm (CH₂OH), 73 ppm (OCH₂), 125 ppm to 131 ppm (Ar, CH), 138 ppm to 144 ppm (Ar, C), 176 ppm (C═O)

### Polymer (P-9)

¹³C-NMR (600 MHZ, CDCl₃): 20 ppm to 50 ppm (α-CH₃, backbone, Ad), 61 ppm to 62 ppm (—OCH₂CH₂OH), 73 ppm (Ad, C—O), 82 ppm (Ad, O—C), 125 ppm to 130 ppm (Ar, CH), 138 ppm to 145 ppm (Ar, C), 178 ppm (C═O)

### Polymer (P-10)

¹³C-NMR (600 MHZ, CDCl₃): 20 ppm to 22 ppm (α-CH₃), 40 ppm to 50 ppm (backbone), 67 ppm (CH₂OH), 71 ppm (OCH₂), 75 ppm (CHOH), 125 ppm to 130 ppm (Ar, CH), 138 ppm to 144 ppm (Ar, C), 176 ppm (C═O)

### Polymer (P-11)

¹³C-NMR (600 MHZ, CDCl₃): 20 ppm to 22 ppm (α-CH₃), 40 ppm to 50 ppm (backbone), 61 ppm to 62 ppm (CH₂OH), 64 ppm (CHOH), 70 ppm to 74 ppm (CH, CHOH), 95 ppm (OCHOH), 125 ppm to 130 ppm (Ar, CH), 138 ppm to 144 ppm (Ar, C), 176 ppm (C═O)

### Polymer (P-12)

¹³C-NMR (600 MHZ, CDCl₃): 20 ppm to 22 ppm (α-CH₃), 38 ppm to 39 ppm (C), 40 ppm to 50 ppm (backbone), 59 ppm to 61 ppm (CH₂OH), 63 ppm (OCH₂), 125 ppm to 130 ppm (Ar, CH), 138 ppm to 144 ppm (Ar, C), 177 ppm (C═O)

### Polymers (P-13) and (P-14)

¹³C-NMR (600 MHZ, CDCl₃): 40 ppm to 50 ppm (backbone), 68 ppm to 69 ppm (CH₂OH), 125 ppm to 130 ppm (Ar, CH), 138 ppm to 144 ppm (Ar, C)

### Polymer (P-17)

¹³C-NMR (600 MHZ, CDCl₃): 19 ppm to 22 ppm (α-CH₃, Ar—CH₃), 40 ppm to 50 ppm (backbone), 63 ppm (CH₂OH), 70 ppm (OCH₂), 127 ppm to 130 ppm (Ar, CH), 135 ppm to 137 ppm (Ar, C), 177 ppm (C═O)

A molar ratio of each constituent unit, a number average molecular weight (Mn), and a molecular weight dispersity (Mw/Mn) determined by the ¹³C-NMR (600 MHZ) of the block copolymers (P-1) to (P-18) are shown in Table 1.

In Comparative Examples, the following polymers (P-19) and (P-20) were also used. A molar ratio of each constituent unit, a number average molecular weight (Mn), and a molecular weight dispersity (Mw/Mn) of the polymers are shown in Table 1.

Polymer (P-19): a random copolymer having a constituent unit represented by the following formula.

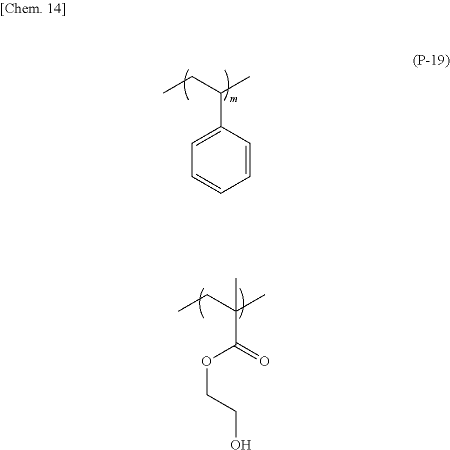

Polymer (P-20): a polymer represented by the following formula.

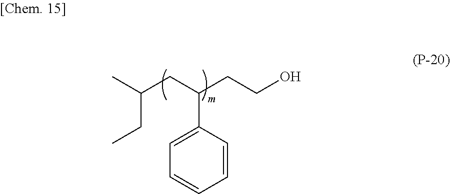

The molar ratio of each constituent unit was calculated by measuring an integral ratio value (area ratio) based on a chemical shift of each constituent unit of the polymer by ¹³C-NMR measurement (600 MHZ, CDCl₃, cumulative number of 1,024 times) using an NMR device (manufactured by Bruker, with CryoProbe).

TABLE 1

| | |
|---|---|
| Constituent | Molar ratio |

| | | | | |
|---|---|---|---|---|
| unit | m | n | Mn | Mw/Mn |

| | | | | | | |
|---|---|---|---|---|---|---|
| P-1 | A-1 | B-1 | 75 | 25 | 1,500 | 1.04 |
| P-2 | A-1 | B-1 | 92 | 8 | 3,800 | 1.05 |
| P-3 | A-1 | B-1 | 90 | 10 | 9,500 | 1.04 |
| P-4 | A-1 | B-1 | 95 | 5 | 9,500 | 1.08 |
| P-5 | A-1 | B-1 | 71 | 29 | 2,200 | 1.05 |
| P-6 | A-1 | B-2 | 85 | 15 | 2,500 | 1.03 |
| P-7 | A-1 | B-3 | 78 | 22 | 2,800 | 1.09 |
| P-8 | A-1 | B-4 | 81 | 19 | 2,900 | 1.08 |
| P-9 | A-1 | B-5 | 75 | 25 | 5,500 | 1.07 |
| P-10 | A-1 | B-6 | 78 | 22 | 5,100 | 1.07 |
| P-11 | A-1 | B-7 | 76 | 24 | 3,200 | 1.09 |
| P-12 | A-1 | B-8 | 78 | 22 | 2,200 | 1.05 |
| P-13 | A-1 | B-9 | 70 | 30 | 2,700 | 1.05 |
| P-14 | A-1 | B-9 | 93 | 7 | 6,600 | 1.04 |
| P-15 | A-1 | B-1 | 77 | 23 | 5,600 | 1.11 |
| P-16 | A-1 | B-1 | 79 | 21 | 3,900 | 1.20 |
| P-17 | A-2 | B-1 | 85 | 15 | 5,500 | 1.04 |
| P-18 | A-1 | B-1 | 50 | 50 | 2,500 | 1.05 |
| P-19 | A-1 | B-1 | 98.9 | 1.1 | 10,300 | 1.61 |
| P-20 | A-1 | — | 100 | — | 5,000 | 1.05 |

### <Preparation of Base Material>

The type of polymer shown in Table 2 was mixed with propylene glycol monomethyl ether acetate (PGMEA) to a concentration of 1.0 mass % to prepare a composition of each example.

### <Synthesis of Block Copolymer Used for Phase Separation>

### [Synthesis of Block Copolymer (BCP-1)]

Under an argon atmosphere, 0.12 g (2.93 mmol) of LiCl and 161 g of THF were charged into a Schlenk flask and cooled to −78° C. After the inside of the flask was dehydrated and degassed, 0.27 ml (1.07 mol/l hexane-cyclohexane mixed solution, 0.29 mmol) of sec-butyllithium as an anionic polymerization initiating agent and subsequently 22.1 ml (192 mmol) of styrene were charged into the flask under an argon atmosphere, and stirred at −78° C. for 30 minutes. Next, 0.077 ml (0.44 mmol) of DPE was charged into the flask and stirred at −78° C. for 30 minutes. Subsequently, 9.03 ml (84.80 mmol) of methyl methacrylate was charged into the flask and stirred at −78° C. for 180 minutes. Further, 1 ml (25 mmol) of methanol as a polymerization terminating agent was charged into the flask at −78° C. to stop the reaction, thereby obtaining a reaction polymerization solution.

The reaction polymerization solution was added dropwise to a large amount of methanol to precipitate a polymer. A precipitated white powder was washed with a large amount of methanol, then washed with a large amount of pure water, and then dried to obtain 21.8 g (yield: 73.8%) of a block copolymer (BCP-1).

A number average molecular weight of the block copolymer (BCP-1) was 98,500, and a molecular weight dispersity thereof was 1.05. With respect to the molar ratio of each constituent unit determined by the ¹³C-NMR (600 MHZ), m was 69.8 mol %, and n was 30.2 mol %.

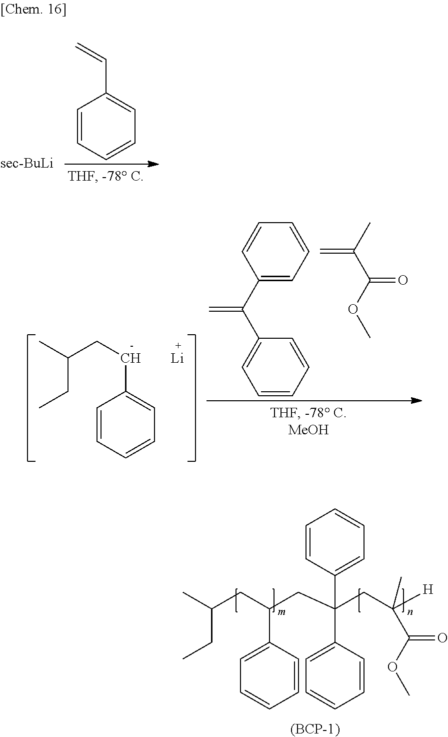

### [Synthesis of Block Copolymer (BCP-2)]

A block copolymer (BCP-2) having a constituent unit represented by the following formula was synthesized in the same manner as in the synthesis of the block copolymer (BCP-1). A number average molecular weight of the block copolymer (BCP-2) was 160,100, and a molecular weight dispersity thereof was 1.03. With respect to the molar ratio of each constituent unit determined by the ¹³C-NMR (600 MHZ), m was 62.5 mol %, and n was 37.5 mol %.

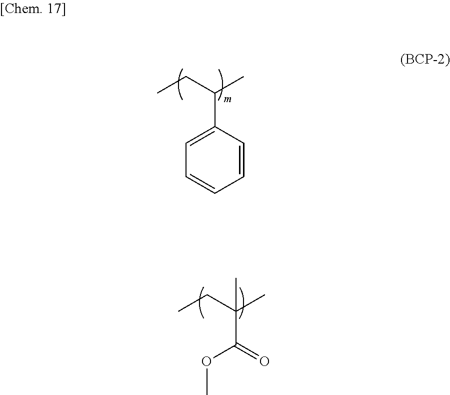

### <Preparation of Resin Composition for Forming Phase-Separated Structure>

First, 100 parts by mass of BCP-1, 14 parts by mass of PS, 6 parts by mass of PMMA, and PGMEA were mixed to prepare a resin composition 1 for forming a phase-separated structure (solid content concentration: about 1.6 mass %).

In addition, 100 parts by mass of BCP-2, 38 parts by mass of PS, 22 parts by mass of PMMA, and PGMEA were mixed to prepare a resin composition 2 for forming a phase-separated structure (solid content concentration: about 2.0 mass %).

The PS and PMMA used are as follows. PS: polystyrene (number average molecular weight: 2,000, molecular weight dispersity: 1.03)

PMMA: polymethyl methacrylate (number average molecular weight: 2,000, molecular weight dispersity: 1.03)

A period of a structure obtained by applying the resin composition 1 for forming a phase-separated structure onto a neutral membrane and performing phase separation was 40 nm. Similarly, a period of a structure obtained by applying the resin composition 2 for forming a phase-separated structure onto a neutral membrane and performing phase separation was 53 nm.

A polymer used for the neutral membrane was a random copolymer of styrene/methyl methacrylate/2-hydroxyethyl methacrylate (copolymerization ratio: 82/12/6 (mass %), number average molecular weight: 45,600, molecular weight dispersity: 1.76).

### <Measurement of Contact Angle of Water on Surface of Base Material Layer>

The base material of each example was applied onto a 12-inch silicon wafer substrate that had been subjected to dehydrobaking at 150° C. for 60 seconds, using a spinner (rotation speed: 1,500 rpm). A coating film was baked and dried at 160° C. or 240° C. for 120 seconds to form a base material layer having a film thickness of 25 nm. The base material layer was rinsed with an OK73 thinner (manufactured by TOKYO OHKA KOGYO CO., LTD.) to remove a polymer that did not adhere to the substrate. Thereafter, baking was performed at 100° C. for 60 seconds.

Water was added dropwise on a surface of the base material layer, and a contact angle (static contact angle) was measured using DROP MASTER-700 (manufactured by Kyowa Interface Science Co., Ltd.) (measurement of contact angle: 2 μL of water). Contact angles when a baking temperature of the base material was set to 160° C. or 240° C. are shown in Table 2 as “160° C.” and “240° C.” of “Contact angle (°)”, respectively. In addition, a difference between the contact angle at 240° C. and the contact angle at 160° C. (contact angle at 240° C.—contact angle at 160° C.) is shown as “Δ” in Table 2.

<Evaluation of Horizontal Orientation when Period of Structure is 40 nm>

### (Step (i))

The base material of each example was applied onto a 12-inch silicon wafer substrate that had been subjected to dehydrobaking at 150° C. for 60 seconds, using a spinner (rotation speed: 1,500 rpm). A coating film was baked and dried at 200° C. for 120 seconds to form a base material layer having a film thickness of 25 nm. The base material layer was rinsed with an OK73 thinner (manufactured by TOKYO OHKA KOGYO CO., LTD.) to remove a polymer that did not adhere to the substrate. Thereafter, baking was performed at 100° C. for 60 seconds.

(Step (ii))

The resin composition 1 for forming a phase-separated structure was applied by spin coating (rotation speed: 1,500 rpm) so as to cover the base material layer. A coating film was baked and dried at 90° C. for 60 seconds to form a layer containing a block copolymer having a film thickness of 52 nm.

(Step (iii))

The layer containing a block copolymer was annealed by heating at 260° C. for 15 minutes in a nitrogen stream to cause phase separation to a phase formed of polystyrene and a phase formed of polymethyl methacrylate, thereby forming a phase-separated structure.

(Step (iv))

The substrate on which the phase-separated structure was formed was irradiated with ultraviolet rays (A172 nm, 160 mJ) under a nitrogen atmosphere using CLEAN TRACK LITHIUS Pro-Z (manufactured by Tokyo Electron Limited.). Thereafter, development was performed with isopropyl alcohol to selectively remove the phase formed of polymethyl methacrylate.

A surface (phase-separated state) of the obtained substrate was observed with a length-measuring SEM (scanning electron microscope, trade name: CG6300, manufactured by Hitachi High-Tech Corporation, accelerating voltage: 800 eV, current value: 15 pA, Frame: 256, magnification: 100 k (image of 1,350 nm square)). Based on results of the observation, the horizontal orientation was evaluated based on the following evaluation criteria. Results thereof are shown in “40 nm” of “Horizontal orientation” in Table 2. A: Complete horizontal orientation (transverse cylinder) was observed. B: A portion of vertical orientation (longitudinal cylinder) was observed.

<Evaluation of Horizontal Orientation when Period of Structure is 53 nm>

A phase-separated structure was formed and the phase formed of polymethyl methacrylate was selectively removed in the same manner as in <Evaluation of Horizontal Orientation when Period of Structure is 40 nm> except that a layer containing a block copolymer having a film thickness of 60 nm was formed using the resin composition 2 for forming a phase-separated structure instead of the resin composition 1 for forming a phase-separated structure in the step (ii) and the layer was annealed at 280° C. in the step (iii).

An image of a surface (phase-separated state) of the obtained substrate was acquired with a length-measuring SEM (scanning electron microscope, trade name: CG6300, manufactured by Hitachi High-Tech Corporation, accelerating voltage: 800 eV, current value: 15 pA, Frame: 256, magnification: 100 k (image of 1,350 nm square)). Based on a result of observing the image, the horizontal orientation was evaluated based on the following evaluation criteria. Results thereof are shown in “53 nm” of “Horizontal orientation” in Table 2. FIG. 5 shows specific examples of images showing phase separation states corresponding to evaluations of A to D.
A: Complete horizontal orientation was observed.
B: An area of a horizontally oriented portion was 90% or more and less than 100% of an image area.
C: The area of the horizontally oriented portion was 50% or more and less than 90% of the image area.
D: The area of the horizontally oriented portion was less than 50% of the image area.

TABLE 2

| | | Contact angle (°) | | | Horizontal orientation | |
|---|---|---|---|---|---|---|
| | Polymer | 160° C. | 240° C. | Δ | 40 nm | 53 nm |
| Example 1 | P-1 | 88.2 | 90.2 | 2.0 | A | A |
| Example 2 | P-2 | 88.1 | 90.2 | 2.1 | A | A |
| Example 3 | P-3 | 89.1 | 90.4 | 1.3 | A | A |
| Example 4 | P-4 | 90.1 | 90.3 | 0.2 | A | A |
| Example 5 | P-5 | 88.8 | 90.2 | 1.4 | A | A |
| Example 6 | P-6 | 89.9 | 90.1 | 0.2 | A | A |
| Example 7 | P-7 | 88.1 | 89.9 | 1.8 | A | A |
| Example 8 | P-8 | 89.0 | 90.0 | 1.0 | A | A |
| Example 9 | P-9 | 88.7 | 91.2 | 2.5 | A | A |
| Example 10 | P-10 | 88.7 | 90.3 | 1.6 | A | A |
| Example 11 | P-11 | 87.4 | 90.0 | 2.6 | A | B |
| Example 12 | P-12 | 87.0 | 89.8 | 2.8 | A | B |
| Example 13 | P-13 | 89.7 | 90.3 | 0.6 | A | A |
| Example 14 | P-14 | 89.9 | 90.3 | 0.4 | A | A |
| Example 15 | P-15 | 88.2 | 90.8 | 2.6 | A | B |
| Example 16 | P-16 | 87.9 | 90.2 | 2.3 | A | B |
| Example 17 | P-17 | 87.7 | 90.1 | 2.4 | A | A |
| Comparative | P-18 | 87.5 | 90.1 | 2.6 | A | C |
| Example 1 | | | | | | |
| Comparative | P-19 | 82.2 | 88.5 | 6.3 | A | D |
| Example 2 | | | | | | |
| Comparative | P-20 | 80.2 | 90.2 | 10.0 | A | D |
| Example 3 | | | | | | |

As shown in Table 2, in Examples 1 to 17 using the predetermined block copolymer (A) for the base material, the contact angle at 160° C. was high, and the difference between the contact angle at 240° C. and the contact angle at 160° C. was small. In addition, in Examples 1 to 17, the horizontal orientation was good even in a case where the period of the structure was relatively large. On the other hand, in Comparative Examples 1 to 3 in which a polymer other than the predetermined block copolymer (A) was used for the base material, even when the horizontal orientation was good in a case where the period of the structure was relatively small, good horizontal orientation was not obtained in the case where the period of the structure was relatively large.

### EXPLANATION OF REFERENCE NUMERALS

1: substrate
2: base material layer
2a: phase 3a-affinitive base material layer
2b: phase 3b-affinitive base material layer
2ab: amphiphilic base material layer
3: layer containing block copolymer
3′: structure
3a: phase
3b: phase

What is claimed is:

1. A base material for bringing a block copolymer-containing layer to phase separation, the base material comprising:
a block copolymer (A) comprising a block (A1) and a block (A2),
wherein the block (A1) has a constituent unit represented by the following Formula (a1),
the block (A2) has a constituent unit represented by the following Formula (a2),
the block copolymer (A) has no constituent unit derived from an alkyl (meth)acrylate,
the block copolymer (A) has a molar ratio of the constituent unit of the block (A2) of more than 0 mol % and 40 mol % or less with respect to a total of the constituent unit of the block (A1) and the constituent unit of the block (A2), 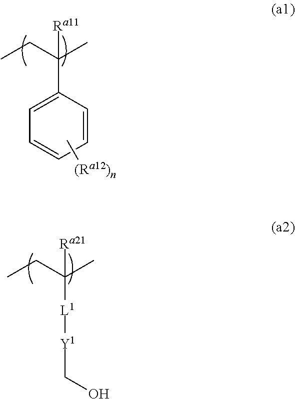
wherein R^{a11} represents a hydrogen atom, an alkyl group having 1 or more and 5 or less carbon atoms, or a halogenated alkyl group having 1 or more and 5 or less carbon atoms, R^{a12} represents a substituent, and n is an integer of 0 or more and 5 or less, and
wherein R^{a21} represents a hydrogen atom, an alkyl group having 1 or more and 5 or less carbon atoms, or a halogenated alkyl group having 1 or more and 5 or less carbon atoms, L¹ represents a single bond or a divalent linking group, and Y¹ represents a divalent linking group having 1 or more and 15 or less carbon atoms.

2. The base material according to claim 1, wherein the block copolymer (A) comprises no block other than the block (A1) and the block (A2).

3. The base material according to claim 1,
wherein the R^{a12} represents an alkyl group having 1 or more and 5 or less carbon atoms,
L¹ represents a single bond or —C(═O)—O—, and
Y¹ represents a divalent hydrocarbon group having 1 or more and 15 or less carbon atoms that may have a substituent.

4. The base material according to claim 1, wherein the molar ratio of the constituent unit of the block (A2) is 3 mol % or more and 35 mol % or less with respect to the total of the constituent unit of the block (A1) and the constituent unit of the block (A2).

5. A method for producing a structure comprising a phase-separated structure, the method comprising:
applying the base material according to claim 1 onto a substrate to form a base material layer;
forming a block copolymer-containing layer on the base material layer; and
bringing the block copolymer-containing layer to phase separation.

6. A method for producing a structure comprising a phase-separated structure, the method comprising:
applying the base material according to claim 2 onto a substrate to form a base material layer;
forming a block copolymer-containing layer on the base material layer; and
bringing the block copolymer-containing layer to phase separation.

7. A method for producing a structure comprising a phase-separated structure, the method comprising:
applying the base material according to claim 3 onto a substrate to form a base material layer;
forming a block copolymer-containing layer on the base material layer; and
bringing the block copolymer-containing layer to phase separation.

8. A method for producing a structure comprising a phase-separated structure, the method comprising:
applying the base material according to claim 4 onto a substrate to form a base material layer;
forming a block copolymer-containing layer on the base material layer; and
bringing the block copolymer-containing layer to phase separation.
